(19) United States
(12) Patent Application Publication
(10) Pub. No.: US 2026/0082683 A1
(43) Pub. Date: Mar. 19, 2026

(54) SEMICONDUCTOR DEVICE

(71) Applicant: ROHM CO., LTD., Kyoto-shi (JP)

(72) Inventors: Kohei MURASAKI, Kyoto-shi (JP); Suguru HONDO, Kyoto-shi (JP)

(73) Assignee: ROHM CO., LTD., Kyoto-shi (JP)

(21) Appl. No.: 19/396,386

(22) Filed: Nov. 21, 2025

Related U.S. Application Data
(63) Continuation of application No. PCT/JP2024/017129, filed on May 8, 2024.

(30) Foreign Application Priority Data
May 22, 2023 (JP) 2023-084042

(51) Int. Cl. H10D 84/00; H10D 8/00; H10D 12/00; H10D 62/10; H10D 64/23

(52) U.S. Cl. CPC H10D 84/161; H10D 8/422; H10D 12/481; H10D 62/103; H10D 62/126; H10D 64/232

(57) ABSTRACT

A semiconductor device includes a chip having first and second principal surfaces, an insulating layer covering the first principal surface, and an extending electrode extending on the first principal surface in a first direction. The extending electrode includes a first electrode layer between the insulating layer and the first principal surface and a second electrode layer, electrically connected to the first electrode layer, on the insulating layer. A first element region includes an element electrically connected to the extending electrode. A second element region, adjacent to the first element region in the first direction, crosses the extending electrode. A second trench electrode structure is in the first principal surface, crosses the extending electrode, and extends across the plurality of second element regions adjacent to each other. The extending electrode does not include the first electrode layer and selectively includes the second electrode layer immediately above the second trench electrode structure.

### CROSS-REFERENCE TO RELATED APPLICATIONS

The present application is a bypass continuation application of International Patent Application No. PCT/JP2024/017129, filed on May 8, 2024, which corresponds to Japanese Patent Application No. 2023-084042, filed on May 22, 2023 with the Japan Patent Office, and the entire disclosures of the applications are incorporated herein by reference.

### TECHNICAL FIELD

The present disclosure relates to a semiconductor device.

### BACKGROUND ART

Patent Literature 1 (WO 2020/080476) discloses an RC-IGBT (Reverse Conducting-Insulated Gate Bipolar Transistor) as an example of a semiconductor device. The RC-IGBT includes an IGBT region and a diode region formed in a semiconductor layer in common. The IGBT region includes an IGBT. The diode region includes a diode.

### BRIEF DESCRIPTION OF DRAWINGS

FIG. 1 is a schematic plan view of a semiconductor device according to a preferred embodiment of the present disclosure.

FIG. 2 is a schematic plan view for explaining an internal structure of the semiconductor device.

FIG. 3 is an enlarged view of a portion surrounded by III in FIG. 2.

FIG. 4 is a cross-sectional view taken along line IV-IV in FIG. 3.

FIG. 5 is a cross-sectional view taken along line V-V in FIG. 3.

FIG. 6 is a cross-sectional view taken along line VI-VI in FIG. 3.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a cross-sectional view taken along line X-X in FIG. 3.

FIG. 11 is a cross-sectional view taken along line XI-XI in FIG. 3.

FIG. 12 is an enlarged view of a portion surrounded by XII in FIG. 2.

FIG. 13 is a cross-sectional view taken along line XIII-XIII in FIG. 12.

FIG. 14 is a view illustrating a modification example of a gate auxiliary trench structure in FIG. 12.

FIG. 15 is a view illustrating a modification example of the gate auxiliary trench structure in FIG. 12.

FIG. 16 is a view illustrating a modification example of the gate auxiliary trench structure in FIG. 12.

FIG. 17 is an enlarged view of a portion surrounded by XVII in FIG. 2.

FIG. 18 is a cross-sectional view taken along line XVIII-XVIII in FIG. 17.

FIG. 19 is a cross-sectional view taken along line XIX-XIX in FIG. 17.

FIG. 20 is a view illustrating a modification example of an arrangement pattern of an IGBT region and a diode region.

FIG. 21 is an enlarged view of a portion surrounded by XXI in FIG. 20.

### DESCRIPTION OF EMBODIMENTS

Next, preferred embodiments of the present disclosure will be described in detail with reference to the accompanying drawings.

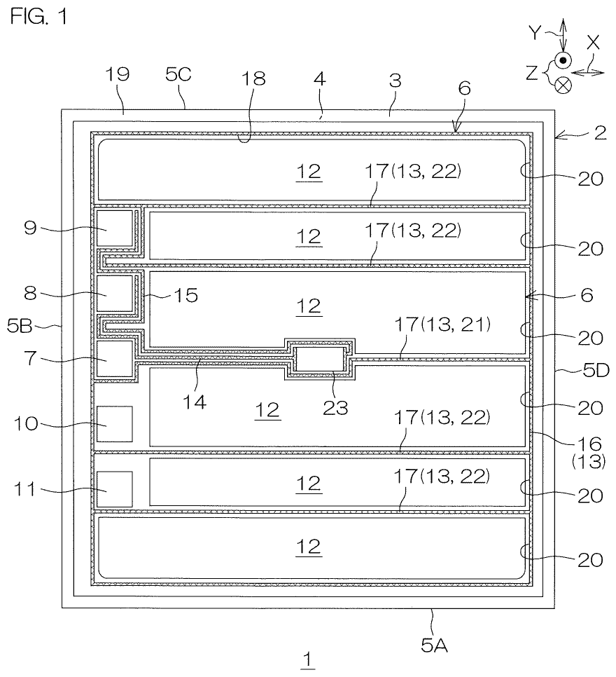

FIG. 1 is a schematic plan view of a semiconductor device 1 according to a preferred embodiment of the present disclosure.

The semiconductor device 1 is an electronic component that has an RC-IGBT (Reverse Conducting-Insulated Gate Bipolar Transistor) that integrally includes an IGBT and a diode. The semiconductor device 1 includes a semiconductor chip 2 of rectangular parallelepiped shape. The semiconductor chip 2 has a first principal surface 3 on one side, a second principal surface 4 on the other side, and side surfaces 5A, 5B, 5C, and 5D connecting the first principal surface 3 and the second principal surface 4.

The first principal surface 3 and the second principal surface 4 are each formed in a quadrilateral shape in plan view as viewed in a normal direction Z thereto (hereinafter, simply referred to as “plan view”). The first principal surface 3 and the second principal surface 4 may be referred to as a front surface and a rear surface of the semiconductor chip 2, respectively. The side surface 5A and the side surface 5C extend along a first direction X and oppose each other in a second direction Y intersecting the first direction X. The side surface 5B and the side surface 5D extend along the second direction Y and oppose each other in the first direction X. Specifically, the second direction Y is orthogonal to the first direction X.

An electrode film 6 is formed on the first principal surface 3. The electrode film 6 includes a plurality of terminal electrodes 7 to 12 and a plurality of wirings 13 to 15. The plurality of terminal electrodes 7 to 11 are arrayed at intervals along the side surface of the semiconductor chip 2. The plurality of terminal electrodes 7 to 11 are concentrated on one side surface (in FIG. 1, the side surface 5B) side of the semiconductor chip 2 and arranged in a line along the side surface 5B.

The electrode film 6 includes a gate terminal electrode 7 and a gate wiring 13 as a configuration related to a gate of the RC-IGBT. The gate wiring 13 transmits a gate signal applied to the gate terminal electrode 7 to the gate of the IGBT.

The gate terminal electrode 7 is disposed at a central position of the plurality of terminal electrodes 7 to 11. The gate wiring 13 integrally includes an annular first portion 16 led out from the gate terminal electrode 7 along the side surfaces 5A to 5D of the semiconductor chip 2, and a second portion 17 crossing an active region 18 surrounded by the first portion 16. The gate wiring 13 may be referred to as a gate finger. In addition, the first portion 16 and the second portion 17 of the gate wiring 13 may be referred to as an outer gate finger and an inner gate finger, respectively. In addition, the first portion 16 and the second portion 17 of the gate wiring 13 may be referred to as an outer extending electrode and an inner extending electrode, respectively.

The active region 18 is a region where the RC-IGBT is formed. A region outside the active region 18 is an outer peripheral region 19. The outer peripheral region 19 extends in a band shape along the peripheral edge of the active region 18. Specifically, the outer peripheral region 19 is set in an endless shape (quadrilateral annular shape) surrounding the active region 18 in plan view.

The active region 18 is divided into a plurality of demarcated regions 20 by the second portion 17 of the gate wiring 13. Each of the plurality of demarcated regions 20 has a rectangular shape extending along the first direction X. The plurality of demarcated regions 20 are adjacent to each other across the second portion 17 of the gate wiring 13.

In this embodiment, the second portions 17 of the plurality of gate wirings 13 cross the active region 18. The plurality of second portions 17 are arrayed at intervals in the second direction Y, and are formed in stripes extending in the first direction X. One end portion and the other end portion of each of the second portions 17 are connected to mutually different positions in the first portion 16. Each of the second portions 17 may have a base end portion (which may be referred to as a terminal-side end portion or a pad-side end portion) on the plurality of terminal electrodes 7 to 11 side connected to the first portion 16, while the opposite end portion may not be connected to the first portion 16 and may serve as a terminal portion.

The plurality of second portions 17 include a central wiring 21 extending from the vicinity of the gate terminal electrode 7 and a plurality of side wirings 22 extending from positions separated from the gate terminal electrode 7 in the second direction Y. In FIG. 1, one central wiring 21 and two each of the side wirings 22 at both sides of the central wiring 21 in the second direction Y are provided. As a result, the active region 18 is divided into six demarcated regions 20.

The electrode film 6 includes an emitter terminal electrode 12 as a configuration related to an emitter of the RC-IGBT. The emitter terminal electrode 12 is disposed in each of the demarcated regions 20. In this embodiment, one emitter terminal electrode 12 is provided in each of the demarcated regions 20. A plurality of emitter terminal electrodes 12 as many as the plurality of demarcated regions 20 are provided. As a matter of course, a plurality of emitter terminal electrodes 12 physically separated from each other may be provided in each of the demarcated regions 20.

The electrode film 6 further includes a first sense terminal electrode 8, a second sense terminal electrode 9, a current detection terminal electrode 10, and an open terminal electrode 11. The first sense terminal electrode 8 and the second sense terminal electrode 9 transmit a control signal for controlling a sensor region 23 (temperature sensor) disposed at the center of the active region 18. The current detection terminal electrode 10 is an electrode for detecting a current flowing through the active region 18 and extracting it to the outside. The open terminal electrode 11 is in an electrically floating state.

The electrode film 6 includes a first sense wiring 14 and a second sense wiring 15. The first sense wiring 14 is electrically connected to the first sense terminal electrode 8. The first sense wiring 14 extends from the outer peripheral region 19 toward the sensor region 23. The first sense wiring 14 transmits a control signal of the temperature sensor. The second sense wiring 15 is electrically connected to the second sense terminal electrode 9. The second sense wiring 15 extends from the outer peripheral region 19 toward the sensor region 23. The second sense wiring 15 transmits a control signal of the temperature sensor. The gate wiring 13 (central wiring 21), the first sense wiring 14, and the second sense wiring 15 run in parallel at intervals in the first direction X.

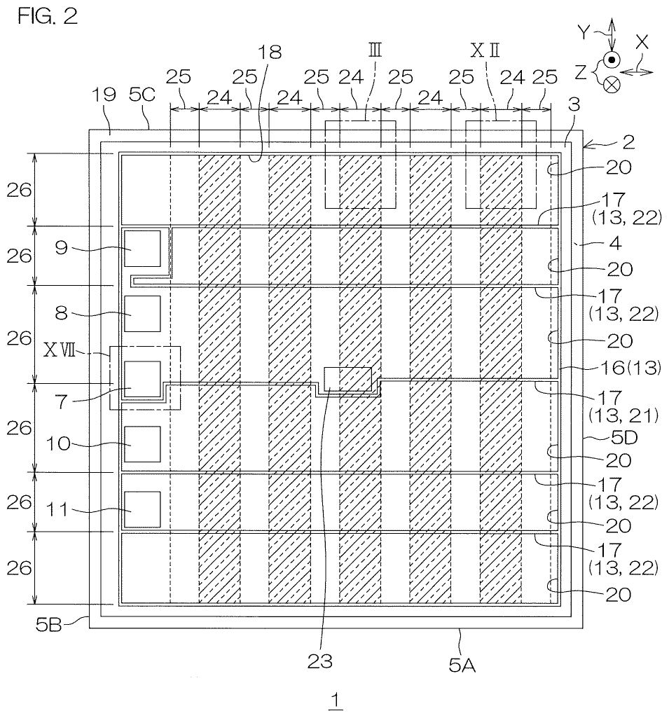

FIG. 2 is a schematic plan view for explaining an internal structure of the semiconductor device 1. In FIG. 2, the terminal electrodes 7 to 11 and the gate wiring 13 in the electrode film 6 are illustrated, and other portions of the electrode film 6 are omitted for clarity.

The active region 18 includes an IGBT region 24 and a diode region 25. In FIG. 2, the IGBT region 24 is shown with hatching for clarity. The IGBT region 24 is a region where the IGBT is formed. The diode region 25 is a region where a diode is formed. The diode region 25 is adjacent to the IGBT region 24.

The active region 18 specifically includes RC-IGBT arrays 26. A plurality of (six in this embodiment) RC-IGBT arrays 26 are formed at intervals in the second direction Y. The adjacent RC-IGBT arrays 26 are separated by the gate wirings 13. The RC-IGBT array 26 has a first end portion on one side (side surface 5B side) and a second end portion on the other side (side surface 5D side). The first end portion of the RC-IGBT array 26 may be referred to as a terminal-side end portion or a pad-side end portion. The second end portion of the RC-IGBT array 26 may be referred to as a terminal-end-side end portion.

The RC-IGBT array 26 has a loop array repeatedly including the diode region 25, the IGBT region 24, the diode region 25, the IGBT region 24, and the diode region 25 ... arrayed in a line along the first direction X from the first end portion toward the second end portion. In this embodiment, the first end portion of the RC-IGBT array 26 is formed by the diode region 25. In this embodiment, the second end portion of the RC-IGBT array 26 is formed by the diode region 25. The first end portion of the RC-IGBT array 26 may be formed by the IGBT region 24. The second end portion of the RC-IGBT array 26 may be formed by the IGBT region 24.

As described above, the plurality of IGBT regions 24 are dispersedly arrayed in the active region 18. The plurality of IGBT regions 24 are formed at intervals along the first direction X and the second direction Y. In this embodiment, the plurality of IGBT regions 24 are arrayed in a matrix in plan view. The plurality of IGBT regions 24 oppose each other along the first direction X and oppose each other along the second direction Y.

In this embodiment, the plurality of IGBT regions 24 are each formed in a quadrilateral shape in plan view. Specifically, the plurality of IGBT regions 24 are each formed in a rectangular shape extending along the second direction Y.

A width WI of each IGBT region 24 in the first direction X may be 10 μm or more and 1000 μm or less. The width WI may be 10 μm or more and 100 μm or less, 100 μm or more and 200 μm or less, 200 μm or more and 300 μm or less, 300 μm or more and 400 μm or less, 400 μm or more and 500 μm or less, 500 μm or more and 600 μm or less, 600 μm or more and 700 μm or less, 700 μm or more and 800 μm or less, 800 μm or more and 900 μm or less, or 900 μm or more and 1000 μm or less. The width WI is preferably 100 μm or more. The width WI is more preferably 200 μm or more.

In the active region 18, the plurality of diode regions 25 are dispersedly arrayed. The plurality of diode regions 25 are formed at intervals along the first direction X and the second direction Y. In this embodiment, the plurality of diode regions 25 are arrayed in a matrix in plan view. The plurality of diode regions 25 oppose each other along the first direction X and oppose each other along the second direction Y.

Specifically, each of the plurality of diode regions 25 is formed such as to be adjacent to the IGBT region 24 in the first direction X. In this embodiment, each of the plurality of diode regions 25 is formed in a quadrilateral shape in plan view. Specifically, each of the plurality of diode regions 25 is formed in a rectangular shape extending along the second direction Y.

A planar area of each diode region 25 is preferably equal to or less than the planar area of each IGBT region 24. The planar area of each diode region 25 is more preferably less than the planar area of each IGBT region 24. A width WD of each diode region 25 in the first direction X is preferably equal to or less than the width WI of each IGBT region 24. The width WD of each diode region 25 is more preferably less than the width WI of each IGBT region 24.

The width WD may be 5 μm or more and less than 1000 μm. The width WD may be 5 μm or more and 100 μm or less, 100 μm or more and 200 μm or less, 200 μm or more and 300 μm or less, 300 μm or more and 400 μm or less, 400 μm or more and 500 μm or less, 500 μm or more and 600 μm or less, 600 μm or more and 700 μm or less, 700 μm or more and 800 μm or less, 800 μm or more and 900 μm or less, or 900 μm or more and less than 1000 μm. The width WD is preferably 100 μm or more. The width WD is more preferably 200 μm or more.

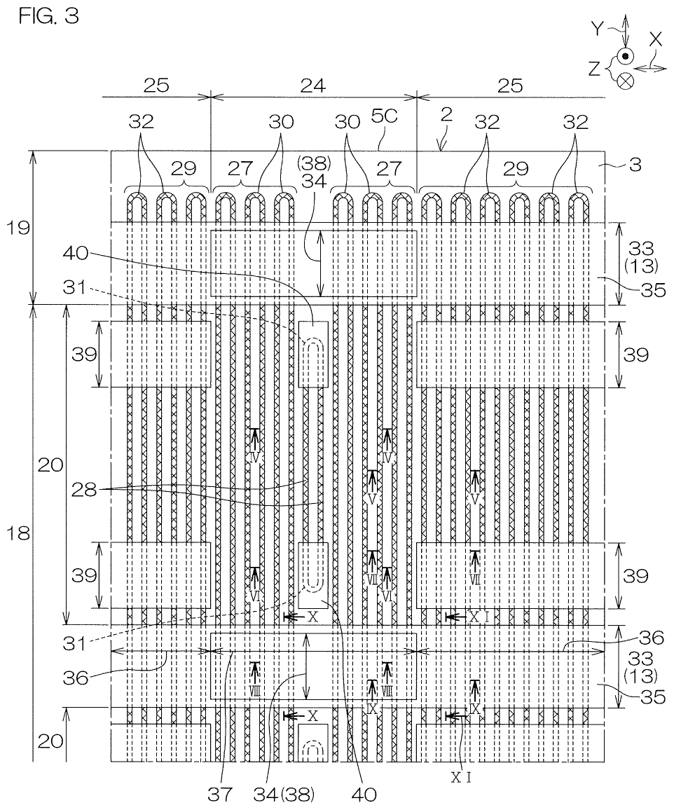

Next, one embodiment of a planar structure of the active region 18 will be described. FIG. 3 is an enlarged view of a portion surrounded by III in FIG. 2, and illustrates a portion of the plurality of IGBT regions 24 and the plurality of diode regions 25. The planar structure of the IGBT region 24 and the diode region 25 described below may be applied to all the IGBT regions 24 and all the diode regions 25 of the semiconductor chip 2, or may be selectively applied to some of the IGBT regions 24 and the diode regions 25. That is, the planar structure described below is a structure applicable to at least one IGBT region 24 and one diode region 25.

Referring to FIG. 3, a plurality of types of trench electrode structures 27 to 29 are formed in stripes in the first principal surface 3 of the semiconductor chip 2. The plurality of trench electrode structures 27 to 29 extend in parallel along the second direction Y. In this embodiment, the plurality of trench electrode structures 27 to 29 are a trench gate structure 27, an emitter trench structure 28, and a diode-side trench structure 29. In FIG. 3, the trench gate structure 27, the emitter trench structure 28, and the diode-side trench structure 29 are shown with hatching.

The plurality of trench gate structures 27 are formed in the IGBT region 24. The trench gate structure 27 is formed in a band shape extending along the second direction Y in plan view. The plurality of trench gate structures 27 are formed in stripes as a whole. The plurality of trench gate structures 27 cross immediately below the gate wiring 13 from one side to the other side in the second direction Y. As a result, the common trench gate structure 27 extends across the plurality of demarcated regions 20. The trench gate structure 27 has a terminal portion 30 on each of one side and the other side in the second direction Y. In FIG. 3, the terminal portion 30 on one side is illustrated.

One each of the terminal portion 30 of the trench gate structure 27 is formed for a pair of trench gate structures 27. The terminal portion 30 connects the adjacent trench gate structures 27 in the outer peripheral region 19. The terminal portion 30 is formed in a round shape in plan view.

The plurality of emitter trench structures 28 are formed in the IGBT region 24. The emitter trench structure 28 is formed in a band shape extending along the second direction Y in plan view. The plurality of emitter trench structures 28 extend side by side with the trench gate structures 27, and are formed in stripes as a whole of the emitter trench structures 28 and the trench gate structures 27. The plurality of emitter trench structures 28 are sandwiched between the plurality of trench gate structures 27 in the first direction X. In this embodiment, a pair of emitter trench structures 28 are sandwiched between the plurality of trench gate structures 27 in the first direction X.

The plurality of emitter trench structures 28 do not cross the gate wiring 13, and have a terminal portion 31 inside the IGBT region 24 separated from the gate wiring 13 in the second direction Y. One each of the terminal portion 31 of the emitter trench structure 28 is formed for a pair of emitter trench structures 28. The terminal portion 31 connects the adjacent emitter trench structures 28 in the IGBT region 24. The terminal portion 31 is formed in a round shape in plan view.

The plurality of diode-side trench structures 29 are formed in the diode region 25. The diode-side trench structure 29 is formed in a band shape extending along the second direction Y in plan view. The plurality of diode-side trench structures 29 are formed in stripes as a whole. The plurality of diode-side trench structures 29 cross immediately below the gate wiring 13 from one side to the other side in the second direction Y. As a result, the common diode-side trench structure 29 extends across the plurality of demarcated regions 20. The diode-side trench structure 29 has a terminal portion 32 on each of one side and the other side in the second direction Y. In FIG. 3, the terminal portion 32 on one side is illustrated.

One each of the terminal portion 32 of the diode-side trench structure 29 is formed for a pair of diode-side trench structures 29. The terminal portion 32 connects the adjacent diode-side trench structures 29 in the outer peripheral region 19. The terminal portion 32 is formed in a round shape in plan view.

The gate wiring 13 is an electrode extending across the plurality of trench gate structures 27 in the first direction X. The gate wiring 13 may be referred to as a gate extending electrode 33. The gate extending electrode 33 includes a first electrode layer 34 and a second electrode layer 35.

The second electrode layer 35 is a layer laminated on the first electrode layer 34. The second electrode layer 35 is an electrode layer appearing at a frontmost surface of the gate extending electrode 33, and may be referred to as a front surface layer. The second electrode layer 35 is a layer having lower resistance than the first electrode layer 34. The outline of the second electrode layer 35 coincides with the outline of the gate extending electrode 33. In this embodiment, the second electrode layer 35 is formed in a band shape extending continuously across the plurality of IGBT regions 24 and the plurality of diode regions 25 arrayed alternately. The second electrode layer 35 has a band shape having a constant width in the second direction Y.

The first electrode layer 34 is formed such as to avoid a region immediately above the diode-side trench structure 29. Specifically, the first electrode layer 34 is selectively separated by a non-contact section 36 in which the second electrode layer 35 and the diode region 25 oppose each other. As a result, the first electrode layer 34 is selectively disposed in a contact section 37 where the second electrode layer 35 and the IGBT region 24 oppose each other. That is, the gate extending electrode 33 does not have the first electrode layer 34 and selectively has the second electrode layer 35 immediately above the trench gate structure 27. The first electrode layer 34 is formed in a band shape that is long in the first direction X, and collectively covers the plurality of trench gate structures 27. The first electrode layer 34 is a layer electrically connected to the plurality of trench gate structures 27, and may be referred to as a first contact layer 38.

A second contact layer 39 is formed on the first principal surface 3 of the semiconductor chip 2. The second contact layer 39 is a layer electrically connected to the plurality of diode-side trench structures 29. The second contact layer 39 is formed in a band shape that is long in the first direction X, and collectively covers the plurality of diode-side trench structures 29. In this embodiment, the second contact layer 39 is separated from the gate extending electrode 33 toward the inside of the diode region 25, and extends parallel to the gate extending electrode 33.

A third contact layer 40 is formed on the first principal surface 3 of the semiconductor chip 2. The third contact layer 40 is a layer electrically connected to the plurality of emitter trench structures 28. The third contact layer 40 is formed in an island shape in plan view, and collectively covers the terminal portion 31 of the pair of emitter trench structures 28.

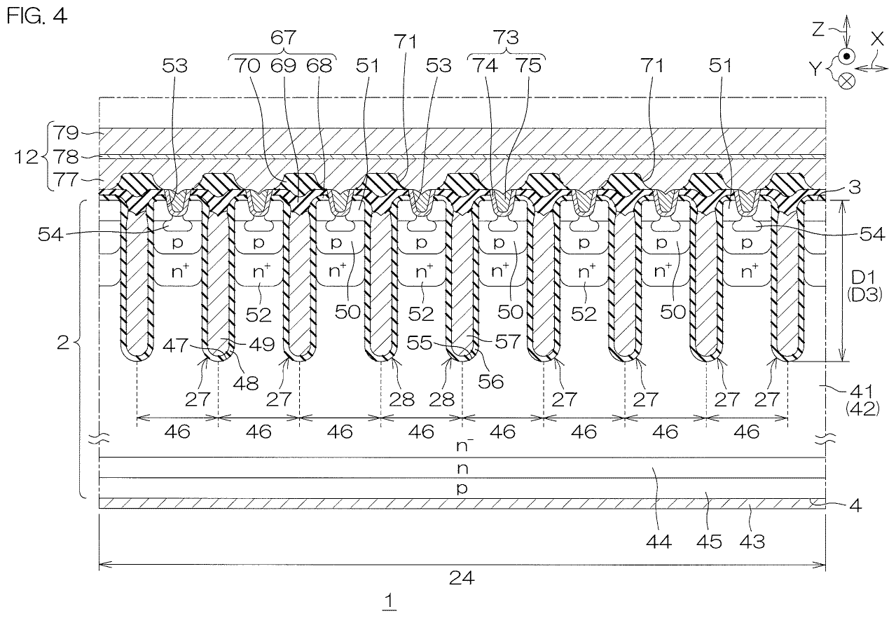

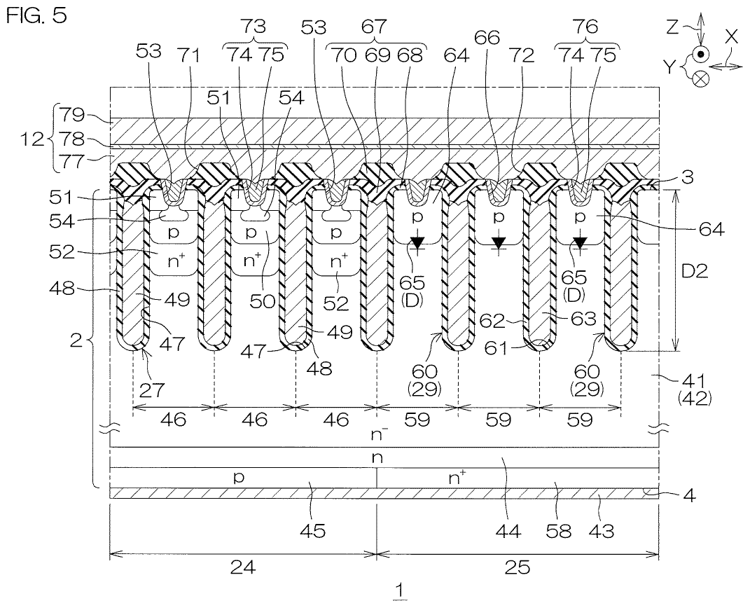

Next, one embodiment of a cross-sectional structure of the active region 18 will be described. FIG. 4 is a cross-sectional view taken along line IV-IV in FIG. 3. FIG. 5 is a cross-sectional view taken along line V-V in FIG. 3. First, a basic cross-sectional structure of the IGBT region 24 and the diode region 25 will be described with reference to FIGS. 4 and 5.

The semiconductor device 1 includes an n⁻ type drift region 41 formed inside the semiconductor chip 2. Specifically, the drift region 41 is formed in an entire region of the semiconductor chip 2 in the first direction X and the second direction Y. The drift region 41 is formed in a surface layer portion of the first principal surface 3 of the semiconductor chip 2 in the normal direction Z (thickness direction of the semiconductor chip 2). The n type impurity concentration of the drift region 41 may be 1.0×10¹³ cm⁻³ or more and 1.0×10¹⁵ cm⁻³ or less.

In this embodiment, the semiconductor chip 2 has a single layer structure including an n⁻ type semiconductor substrate 42. The semiconductor substrate 42 may be an FZ substrate made of silicon formed through an FZ (floating zone) method. The drift region 41 is formed by the semiconductor substrate 42.

The semiconductor device 1 includes a collector terminal electrode 43 formed on the second principal surface 4 of the semiconductor chip 2. The collector terminal electrode 43 is electrically connected to the second principal surface 4. Specifically, the collector terminal electrode 43 is electrically connected to the IGBT region 24 (collector region 45 to be described later) and the diode region 25 (cathode region 58 to be described later). The collector terminal electrode 43 forms an ohmic contact with the second principal surface 4. The collector terminal electrode 43 transmits a collector signal to the IGBT region 24 and the diode region 25.

The collector terminal electrode 43 may include at least one of a Ti layer, an Ni layer, an Au layer, an Ag layer, and an Al layer. The collector terminal electrode 43 may have a single layer structure including a Ti layer, an Ni layer, an Au layer, an Ag layer, or an Al layer. The collector terminal electrode 43 may have a laminated structure in which at least two of a Ti layer, an Ni layer, an Au layer, an Ag layer, and an Al layer are laminated in an arbitrary manner.

The semiconductor device 1 includes an n type buffer layer 44 formed in a surface layer portion of the second principal surface 4 of the semiconductor chip 2. The buffer layer 44 may be formed in the entire surface layer portion of the second principal surface 4. The n type impurity concentration of the buffer layer 44 is greater than the n type impurity concentration of the drift region 41. The n type impurity concentration of the buffer layer 44 may be 1.0×10¹⁵ cm⁻³ or more and 1.0×10¹⁷ cm⁻³ or less.

A thickness of the buffer layer 44 may be 0.5 μm or more and 30 μm or less. The thickness of the buffer layer 44 may be 0.5 μm or more and 5 μm or less, 5 μm or more and 10 μm or less, 10 μm or more and 15 μm or less, 15 μm or more and 20 μm or less, 20 μm or more and 25 μm or less, or 25 μm or more and 30 μm or less.

Each IGBT region 24 includes a p type collector region 45 formed in the surface layer portion of the second principal surface 4 of the semiconductor chip 2. The collector region 45 is exposed from the second principal surface 4. The collector region 45 may be formed in an entire region of the IGBT region 24 in the surface layer portion of the second principal surface 4. The p type impurity concentration of the collector region 45 may be 1.0×10¹⁵ cm⁻³ or more and 1.0×10¹⁸ cm⁻³ or less. The collector region 45 forms an ohmic contact with the collector terminal electrode 43.

Each IGBT region 24 includes an FET structure 46 formed on the first principal surface 3 of the semiconductor chip 2. In this embodiment, each IGBT region 24 includes a trench gate type FET structure 46. The FET structure 46 specifically includes a trench gate structure 27 formed on the first principal surface 3.

A plurality of trench gate structures 27 are formed at intervals along the first direction X in the IGBT region 24. A distance between the two trench gate structures 27 adjacent to each other in the first direction X may be 1 μm or more and 8 μm or less. The distance between the two trench gate structures 27 may be 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, or 7 μm or more and 8 μm or less.

Each trench gate structure 27 includes a gate trench 47, a gate insulating layer 48, and a gate electrode layer 49. The gate trench 47 is formed in the first principal surface 3. The gate trench 47 includes a side wall and a bottom wall. The side wall of the gate trench 47 may be formed perpendicularly to the first principal surface 3.

The side wall of the gate trench 47 may be inclined downward from the first principal surface 3 toward the bottom wall. The gate trench 47 may be formed in a tapered shape in which an opening area on the opening side is larger than the bottom surface area. The bottom wall of the gate trench 47 may be formed in parallel with the first principal surface 3. The bottom wall of the gate trench 47 may be formed in a curved shape toward the second principal surface 4. The gate trench 47 includes a bottom wall edge portion. The bottom wall edge portion connects the side wall and the bottom wall of the gate trench 47. The bottom wall edge portion may be formed in a curved shape toward the second principal surface 4.

A depth D1 of the gate trench 47 may be 2 μm or more and 10 μm or less. The depth D1 of the gate trench 47 may be 2 μm or more and 3 μm or less, 3 μm or more and 4 μm or less, 4 μm or more and 5 μm or less, 5 μm or more and 6 μm or less, 6 μm or more and 7 μm or less, 8 μm or more and 9 μm or less, or 9 μm or more and 10 μm or less. The depth D1 of the gate trench 47 may be defined as a distance between a depth position of the deepest portion of the bottom wall of the gate trench 47 and the first principal surface 3.

A width of the gate trench 47 may be 0.5 μm or more and 3 μm or less. The width of the gate trench 47 is a width of the gate trench 47 in the first direction X. The width of the gate trench 47 may be 0.5 μm or more and 1 μm or less, 1 μm or more and 1.5 μm or less, 1.5 μm or more and 2 μm or less, 2 μm or more and 2.5 μm or less, or 2.5 μm or more and 3 μm or less.

The gate insulating layer 48 is formed in a film shape along an inner wall of the gate trench 47. The gate insulating layer 48 demarcates a recess space in the gate trench 47. In this embodiment, the gate insulating layer 48 includes a silicon oxide film. The gate insulating layer 48 may include a silicon nitride film instead of or in addition to the silicon oxide film.

The gate electrode layer 49 is embedded in the gate trench 47 across the gate insulating layer 48. Specifically, the gate electrode layer 49 is embedded in the recess space demarcated by the gate insulating layer 48 in the gate trench 47. The gate electrode layer 49 is controlled by a gate signal. The gate electrode layer 49 may contain a conductive polysilicon.

The FET structure 46 includes a p type body region 50 formed in the surface layer portion of the first principal surface 3 of the semiconductor chip 2. The p type impurity concentration of the body region 50 may be 1.0×10¹⁷ cm⁻³ or more and 1.0×10¹⁸ cm⁻³ or less. The body regions 50 are respectively formed at both sides of the trench gate structure 27. The body region 50 is formed in a band shape extending along the trench gate structure 27 in plan view. The body region 50 is exposed from the side wall of the gate trench 47. A bottom portion of the body region 50 is formed in a region between the first principal surface 3 and the bottom wall of the gate trench 47 in the normal direction Z.

The FET structure 46 includes an n⁺ type emitter region 51 formed in a surface layer portion of the body region 50. The n type impurity concentration of the emitter region 51 is greater than the n type impurity concentration of the drift region 41. The n type impurity concentration of the emitter region 51 may be 1.0×10¹⁹ cm⁻³ or more and 1.0×10²⁰ cm⁻³ or less.

In this embodiment, the FET structure 46 includes a plurality of emitter regions 51 formed at both sides of the trench gate structure 27. The emitter region 51 is formed in a band shape extending along the trench gate structure 27 in plan view. The emitter region 51 is exposed from the first principal surface 3 and the side wall of the gate trench 47. A bottom portion of the emitter region 51 is formed in a region between an upper end portion of the gate electrode layer 49 and the bottom portion of the body region 50 in the normal direction Z.

In this embodiment, the FET structure 46 includes an n⁺ type carrier storage region 52 formed in a region on the second principal surface 4 side with respect to the body region 50 in the semiconductor chip 2. The n type impurity concentration of the carrier storage region 52 is greater than the n type impurity concentration of the drift region 41. The n type impurity concentration of the carrier storage region 52 may be 1.0×10¹⁵ cm⁻³ or more and 1.0×10¹⁷ cm⁻³ or less.

In this embodiment, the FET structure 46 includes a plurality of carrier storage regions 52 formed at both sides of the trench gate structure 27. The carrier storage region 52 is formed in a band shape extending along the trench gate structure 27 in plan view. The carrier storage region 52 is exposed from the side wall of the gate trench 47. A bottom portion of the carrier storage region 52 is formed in a region between the bottom portion of the body region 50 and the bottom wall of the gate trench 47 in the normal direction Z.

The carrier storage region 52 suppresses carriers (holes) supplied to the semiconductor chip 2 from being drawn back (drained) to the body region 50. As a result, holes are accumulated in a region immediately below the FET structure 46 in the semiconductor chip 2. As a result, the reduction of the on resistance and the reduction of the on voltage are achieved.

The FET structure 46 includes a contact trench 53 formed in the first principal surface 3 of the semiconductor chip 2. In this embodiment, the FET structure 46 includes a plurality of contact trenches 53 formed at both sides of the trench gate structure 27. The contact trench 53 exposes the emitter region 51. In this embodiment, the contact trench 53 penetrates through the emitter region 51.

The contact trench 53 is formed at an interval in the first direction X from the trench gate structure 27. The contact trench 53 extends in a band shape along the trench gate structure 27 in plan view.

The FET structure 46 includes a p⁺ type contact region 54 formed in a region along a bottom wall of the contact trench 53 in the body region 50. The p type impurity concentration of the contact region 54 is greater than the p type impurity concentration of the body region 50. The p type impurity concentration of the contact region 54 may be 1.0×10¹⁹ cm⁻³ or more and 1.0×10²⁰ cm⁻³ or less.

The contact region 54 is exposed from the bottom wall of the contact trench 53. The contact region 54 extends in a band shape along the contact trench 53 in plan view. A bottom portion of the contact region 54 is formed in a region between the bottom wall of the contact trench 53 and the bottom portion of the body region 50 in the normal direction Z.

As described above, in the FET structure 46, the gate electrode layer 49 opposes the body region 50 and the emitter region 51 across the gate insulating layer 48. In this embodiment, the gate electrode layer 49 also opposes the carrier storage region 52 across the gate insulating layer 48. An IGBT channel is formed in a region between the emitter region 51 and the drift region 41 (carrier storage region 52) in the body region 50. ON/OFF of the channel is controlled by the gate signal.

Each IGBT region 24 includes the emitter trench structure 28 in the first principal surface 3 of the semiconductor chip 2. Each IGBT region 24 specifically includes a plurality of emitter trench structures 28 formed at both sides of the FET structure 46. The emitter trench structure 28 is formed in a region adjacent to the FET structure 46 in the surface layer portion of the first principal surface 3. The emitter trench structure 28 is formed in a band shape extending along the second direction Y in plan view. The emitter trench structure 28 may have a band shape parallel to the trench gate structure 27.

The emitter trench structure 28 includes an emitter trench 55, an emitter insulating layer 56, and an emitter potential electrode layer 57. The emitter trench 55 is formed in the first principal surface 3 of the semiconductor chip 2. The emitter trench 55 includes a side wall and a bottom wall. The side wall of the emitter trench 55 may be formed perpendicularly to the first principal surface 3.

The side wall of the emitter trench 55 may be inclined downward from the first principal surface 3 toward the bottom wall. The emitter trench 55 may be formed in a tapered shape in which the opening area on the opening side is larger than the bottom surface area. The emitter region 51, the body region 50, and the carrier storage region 52 are exposed from the side wall (outer side wall) facing the FET structure 46 in the emitter trench 55. The bottom wall of the emitter trench 55 may be formed in parallel with the first principal surface 3. The bottom wall of the emitter trench 55 may be formed in a curved shape toward the second principal surface 4. The emitter trench 55 includes a bottom wall edge portion. The bottom wall edge portion connects the side wall and the bottom wall of the emitter trench 55. The bottom wall edge portion may be formed in a curved shape toward the second principal surface 4 of the semiconductor chip 2.

A depth D3 of the emitter trench 55 may be 2 μm or more and 10 μm or less. The depth D3 of the emitter trench 55 may be 2 μm or more and 3 μm or less, 3 μm or more and 4 μm or less, 4 μm or more and 5 μm or less, 5 μm or more and 6 μm or less, 6 μm or more and 7 μm or less, 8 μm or more and 9 μm or less, or 9 μm or more and 10 μm or less. The depth D3 of the emitter trench 55 may be equal to the depth D1 of the gate trench 47.

The width of the emitter trench 55 may be 0.5 μm or more and 3 μm or less. The width of the emitter trench 55 is a width of the emitter trench 55 in the first direction X. The width of the emitter trench 55 may be 0.5 μm or more and 1 μm or less, 1 μm or more and 1.5 μm or less, 1.5 μm or more and 2 μm or less, 2 μm or more and 2.5 μm or less, or 2.5 μm or more and 3 μm or less. The width of the emitter trench 55 may be equal to the width of the gate trench 47.

The emitter insulating layer 56 is formed in a film shape along an inner wall of the emitter trench 55. The emitter insulating layer 56 demarcates a recess space in the emitter trench 55. In this embodiment, the emitter insulating layer 56 includes a silicon oxide film. The emitter insulating layer 56 may include a silicon nitride film instead of or in addition to the silicon oxide film.

The emitter potential electrode layer 57 is embedded in the emitter trench 55 across the emitter insulating layer 56. Specifically, the emitter potential electrode layer 57 is embedded in the recess space demarcated by the emitter insulating layer 56 in the emitter trench 55. The emitter potential electrode layer 57 may contain a conductive polysilicon. The emitter potential electrode layer 57 is controlled by an emitter signal.

Referring to FIG. 5, each diode region 25 includes an n⁺ type cathode region 58 (second impurity region) formed in the surface layer portion of the second principal surface 4 of the semiconductor chip 2. The n type impurity concentration of the cathode region 58 is greater than the n type impurity concentration of the drift region 41. The n type impurity concentration of the cathode region 58 may be 1.0×10¹⁹ cm⁻³ or more and 1.0×10²⁰ cm⁻³ or less. The cathode region 58 is exposed from the second principal surface 4. The cathode region 58 forms an ohmic contact with the collector terminal electrode 43.

Each diode region 25 includes a cell separation structure 60 that demarcates a diode cell region 59. Each diode region 25 specifically includes a plurality of cell separation structures 60 that respectively demarcate a plurality of diode cell regions 59. The cell separation structure 60 corresponds to the diode-side trench structure 29 in FIG. 3.

The cell separation structure 60 includes a cell separation trench 61, a cell separation insulating layer 62, and a cell separation electrode layer 63. The cell separation trench 61 is formed in the first principal surface 3. The cell separation trench 61 includes a side wall and a bottom wall. The side wall of the cell separation trench 61 may be formed perpendicularly to the first principal surface 3.

The side wall of the cell separation trench 61 may be inclined downward from the first principal surface 3 toward the bottom wall. The cell separation trench 61 may be formed in a tapered shape in which the opening area on the opening side is larger than the bottom surface area. The bottom wall of the cell separation trench 61 may be formed in parallel with the first principal surface 3. The bottom wall of the cell separation trench 61 may be formed in a curved shape toward the second principal surface 4. The cell separation trench 61 includes a bottom wall edge portion. The bottom wall edge portion connects the side wall and the bottom wall of the cell separation trench 61. The bottom wall edge portion may be formed in a curved shape toward the second principal surface 4.

A depth D2 of the cell separation trench 61 may be 2 μm or more and 10 μm or less. The depth D2 of the cell separation trench 61 may be 2 μm or more and 3 μm or less, 3 μm or more and 4 μm or less, 4 μm or more and 5 μm or less, 5 μm or more and 6 μm or less, 6 μm or more and 7 μm or less, 8 μm or more and 9 μm or less, or 9 μm or more and 10 μm or less. The depth D2 of the cell separation trench 61 may be equal to the depth D1 of the gate trench 47. The depth D2 of the cell separation trench 61 may be defined as a distance between the depth position of the deepest portion of the bottom wall of the cell separation trench 61 and the first principal surface 3.

The width of the cell separation trench 61 may be 0.5 μm or more and 3 μm or less. The width of the cell separation trench 61 is a width of the cell separation trench 61 in the first direction X. The width of the cell separation trench 61 may be 0.5 μm or more and 1 μm or less, 1 μm or more and 1.5 μm or less, 1.5 μm or more and 2 μm or less, 2 μm or more and 2.5 μm or less, or 2.5 μm or more and 3 μm or less. The width of the cell separation trench 61 may be equal to the width of the gate trench 47.

The cell separation insulating layer 62 is formed in a film shape along an inner wall of the cell separation trench 61. The cell separation insulating layer 62 demarcates a recess space in the cell separation trench 61. In this embodiment, the cell separation insulating layer 62 includes a silicon oxide film. The cell separation insulating layer 62 may include a silicon nitride film instead of or in addition to the silicon oxide film.

The cell separation electrode layer 63 is embedded in the cell separation trench 61 across the cell separation insulating layer 62. Specifically, the cell separation electrode layer 63 is embedded in the recess space demarcated by the cell separation insulating layer 62 in the cell separation trench 61. The cell separation electrode layer 63 is controlled by an emitter signal. The cell separation electrode layer 63 may contain a conductive polysilicon.

Each diode region 25 includes a p⁻ type anode region 64 (first impurity region) formed in the surface layer portion of the first principal surface 3 of the semiconductor chip 2. The p type impurity concentration of the anode region 64 may be equal to or less than the p type impurity concentration of the body region 50. The p type impurity concentration of the anode region 64 is preferably less than the p type impurity concentration of the body region 50. The p type impurity concentration of the anode region 64 may be 1.0×10¹⁵ cm⁻³ or more and less than 1.0×10¹⁸ cm⁻³.

The anode region 64 is formed in each diode cell region 59. Therefore, a plurality of anode regions 64 are arrayed at equal intervals in the first direction X, and are formed in stripes as a whole.

The anode region 64 forms a pn junction portion 65 with the semiconductor chip 2. As a result, a pn junction diode D having the anode region 64 as an anode and the semiconductor chip 2 (cathode region 58) as a cathode is formed.

The anode region 64 includes a diode trench 66 formed in the first principal surface 3 of the semiconductor chip 2. In this embodiment, the anode region 64 includes a plurality of diode trenches 66 formed at both sides of the cell separation structure 60. The diode trench 66 exposes the anode region 64. The diode trench 66 is formed at an interval from the cell separation structure 60 in the first direction X. The diode trench 66 extends in a band shape along the cell separation structure 60 in plan view.

The semiconductor device 1 includes an interlayer insulating layer 67 formed on the first principal surface 3 of the semiconductor chip 2. The interlayer insulating layer 67 is formed in a film shape along the first principal surface 3 and selectively covers the first principal surface 3. Specifically, the interlayer insulating layer 67 selectively covers the IGBT region 24 and the diode region 25.

The interlayer insulating layer 67 may contain silicon oxide or silicon nitride. The interlayer insulating layer 67 may contain at least one type of material among NSG (non-doped silicate glass), PSG (phosphor silicate glass), and BPSG (boron phosphor silicate glass).

The thickness of the interlayer insulating layer 67 may be 0.1 μm or more and 1 μm or less. The thickness of the interlayer insulating layer 67 may be 0.1 μm or more and 0.2 μm or less, 0.2 μm or more and 0.4 μm or less, 0.4 μm or more and 0.6 μm or less, 0.6 μm or more and 0.8 μm or less, or 0.8 μm or more and 1 μm or less.

In this embodiment, the interlayer insulating layer 67 has a laminated structure including a first insulating layer 68, a second insulating layer 69, and a third insulating layer 70 laminated in this order from the first principal surface 3 side. The first insulating layer 68 preferably contains silicon oxide (for example, a thermal oxide film). The second insulating layer 69 preferably includes an NGS layer. The second insulating layer 69 may include a PSG layer or a BPSG layer instead of the NGS layer. The third insulating layer 70 preferably includes a BPSG layer. The third insulating layer 70 may include an NGS layer or a PSG layer instead of the BPSG layer. The third insulating layer 70 preferably contains an insulating material with a property different from that of the second insulating layer 69.

The first insulating layer 68 is formed in a film shape on the first principal surface 3. The first insulating layer 68 is continuous with the gate insulating layer 48, the emitter insulating layer 56, and the cell separation insulating layer 62. The second insulating layer 69 is formed in a film shape on the first insulating layer 68. The third insulating layer 70 is formed in a film shape on the second insulating layer 69.

The thickness of the first insulating layer 68 may be 500 Å or more and 2000 Å or less. The thickness of the first insulating layer 68 may be 500 Å or more and 1000 Å or less, 1000 Å or more and 1500 Å or less, or 1500 Å or more and 2000 Å or less.

The thickness of the second insulating layer 69 may be 500 Å or more and 4000 Å or less. The thickness of the second insulating layer 69 may be 500 Å or more and 1000 Å or less, 1000 Å or more and 1500 Å or less, 1500 Å or more and 2000 Å or less, 2000 Å or more and 2500 Å or less, 2500 Å or more and 3000 Å or less, 3000 Å or more and 3500 Å or less, or 3500 Å or more and 4000 Å or less.

The thickness of the third insulating layer 70 may be 1000 Å or more and 8000 Å or less. The thickness of the third insulating layer 70 may be 1000 Å or more and 2000 Å or less, 2000 Å or more and 4000 Å or less, 4000 Å or more and 6000 Å or less, or 6000 Å or more and 8000 Å or less.

The interlayer insulating layer 67 includes an emitter opening 71. The emitter opening 71 exposes the contact trench 53. The emitter opening 71 communicates with the contact trench 53. In this embodiment, the contact trench 53 is formed in the first principal surface 3 penetrating through the first insulating layer 68 and the second insulating layer 69. The emitter opening 71 penetrates through the third insulating layer 70 and exposes the contact trench 53. The emitter opening 71 forms one opening with the contact trench 53. An opening edge portion of the emitter opening 71 is formed in a curved shape toward the inside of the interlayer insulating layer 67. As a result, the emitter opening 71 has an opening width larger than the opening width of the contact trench 53.

Referring to FIG. 5, the interlayer insulating layer 67 includes a diode opening 72. The diode opening 72 exposes the diode trench 66. The diode opening 72 communicates with the diode trench 66. In this embodiment, the diode opening 72 is formed in the first principal surface 3 penetrating through the first insulating layer 68 and the second insulating layer 69. The diode opening 72 penetrates through the third insulating layer 70 and exposes the diode trench 66. The diode opening 72 forms one opening with the diode trench 66. An opening edge portion of the diode opening 72 is formed in a curved shape toward the inside of the interlayer insulating layer 67. As a result, the diode opening 72 has an opening width larger than the opening width of the diode trench 66.

The semiconductor device 1 includes an emitter plug electrode 73 embedded in a portion covering the IGBT region 24 in the interlayer insulating layer 67. The emitter plug electrode 73 penetrates through the interlayer insulating layer 67 and is electrically connected to the emitter region 51 and the contact region 54. Specifically, the emitter plug electrode 73 is embedded in the contact trench 53. The emitter plug electrode 73 is electrically connected to the emitter region 51 and the contact region 54 in the contact trench 53.

In this embodiment, the emitter plug electrode 73 has a laminated structure including a barrier electrode layer 74 and a main electrode layer 75. The barrier electrode layer 74 is formed in a film shape along an inner wall of the contact trench 53 such as to be in contact with the interlayer insulating layer 67. The barrier electrode layer 74 demarcates a recess space in the contact trench 53.

The barrier electrode layer 74 may have a single layer structure including a titanium layer or a titanium nitride layer. The barrier electrode layer 74 may have a laminated structure including a titanium layer and a titanium nitride layer. In this case, the titanium nitride layer may be laminated on the titanium layer.

The main electrode layer 75 is embedded in the contact trench 53 across the barrier electrode layer 74. Specifically, the main electrode layer 75 is embedded in the recess space demarcated by the barrier electrode layer 74 in the contact trench 53. The main electrode layer 75 may contain tungsten.

The semiconductor device 1 includes a diode plug electrode 76 embedded in the diode opening 72. The diode plug electrode 76 is electrically connected to the anode region 64 in the diode opening 72. The diode plug electrode 76 has a structure corresponding to the emitter plug electrode 73. Description of the emitter plug electrode 73 applies to description concerning the diode plug electrode 76. In the diode plug electrode 76, structures corresponding to structures described for the emitter plug electrode 73 shall be provided with the same reference signs and description thereof shall be omitted.

The emitter terminal electrode 12 described above is formed on the interlayer insulating layer 67. The emitter terminal electrode 12 may contain at least one type of material among aluminum, copper, aluminum-silicon-copper alloy, aluminum-silicon alloy, and aluminum-copper alloy.

The emitter terminal electrode 12 may have a single layer structure that contains one type of material among the above conductive materials. The emitter terminal electrode 12 may have a laminated structure in which at least two types of materials among the above conductive materials are laminated in any order.

The thickness of the emitter terminal electrode 12 may be 1.0 μm or more and 6.0 μm or less. The thickness of the emitter terminal electrode 12 may be 1.0 μm or more and 2.0 μm or less, 2.0 μm or more and 4.0 μm or less, or 4.0 μm or more and 6.0 μm or less.

In this embodiment, the emitter terminal electrode 12 has a laminated structure including a first electrode layer 77, a second electrode layer 78, and a third electrode layer 79 laminated in this order from the first principal surface 3 side. The first electrode layer 77 preferably contains an aluminum-silicon-copper alloy (Al—Si—Cu). The second electrode layer 78 preferably contains titanium nitride (TiN). The second electrode layer 78 may be referred to as a barrier layer. The third electrode layer 79 preferably contains an aluminum-copper alloy (Al—Cu).

The emitter terminal electrode 12 is electrically connected to the emitter region 51 and the contact region 54 through the emitter plug electrode 73 on the interlayer insulating layer 67. Specifically, the emitter terminal electrode 12 enters into the emitter opening 71 from above the interlayer insulating layer 67. The emitter terminal electrode 12 is electrically connected to the emitter plug electrode 73 in the emitter opening 71. Thus, the emitter terminal electrode 12 is electrically connected to the emitter region 51 and the contact region 54 through the emitter plug electrode 73.

Referring to FIG. 5, the emitter terminal electrode 12 is further electrically connected to the anode region 64 through the diode plug electrode 76 on the interlayer insulating layer 67. Specifically, the emitter terminal electrode 12 enters into the diode opening 72 from above the interlayer insulating layer 67. The emitter terminal electrode 12 functions as an anode terminal electrode in the diode region 25.

The emitter terminal electrode 12 is in contact with an inner wall of the diode opening 72. The emitter terminal electrode 12 is electrically connected to the anode region 64 in the diode opening 72. The emitter terminal electrode 12 is electrically connected to the diode plug electrode 76 in the diode opening 72.

Although specific illustration is omitted, the gate terminal electrode 7, the first sense terminal electrode 8, the second sense terminal electrode 9, the current detection terminal electrode 10, and the open terminal electrode 11 are formed on the interlayer insulating layer 67 similarly to the emitter terminal electrode 12.

The plurality of terminal electrodes 7 to 12 may each contain at least one type of material among aluminum, copper, aluminum-silicon-copper alloy, aluminum-silicon alloy, and aluminum-copper alloy. The plurality of terminal electrodes 7 to 12 may each have a single layer structure that contains one type of material among the above conductive materials. The plurality of terminal electrodes 7 to 12 may each have a laminated structure in which at least two types of materials among the above conductive materials are laminated in any order. In this embodiment, the plurality of terminal electrodes 7 to 12 contain the same conductive material as the emitter terminal electrode 12.

If a lead wire (for example, a bonding wire) is to be connected to each of the plurality of terminal electrodes 7 to 12, a single layer electrode constituted of a nickel layer or a gold layer or a laminated electrode that includes a nickel layer and a gold layer may be formed on each of the plurality of terminal electrodes 7 to 12. In the laminated electrode, the gold layer may be formed on the nickel layer.

In addition, the plurality of wirings 13 to 15 may each contain at least one type of material among aluminum, copper, aluminum-silicon-copper alloy, aluminum-silicon alloy, and aluminum-copper alloy. The plurality of wirings 13 to 15 may each have a single layer structure that contains one type of material among the above conductive materials. The plurality of wirings 13 to 15 may each have a laminated structure in which at least two types of materials among the above conductive materials are laminated in any order. In this embodiment, the plurality of wirings 13 to 15 contain the same conductive material as the emitter terminal electrode 12.

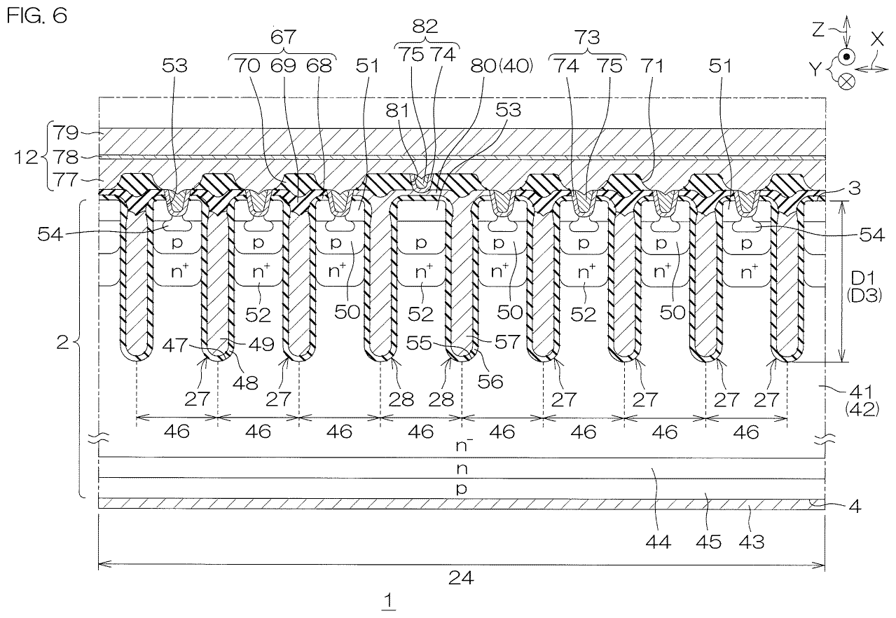

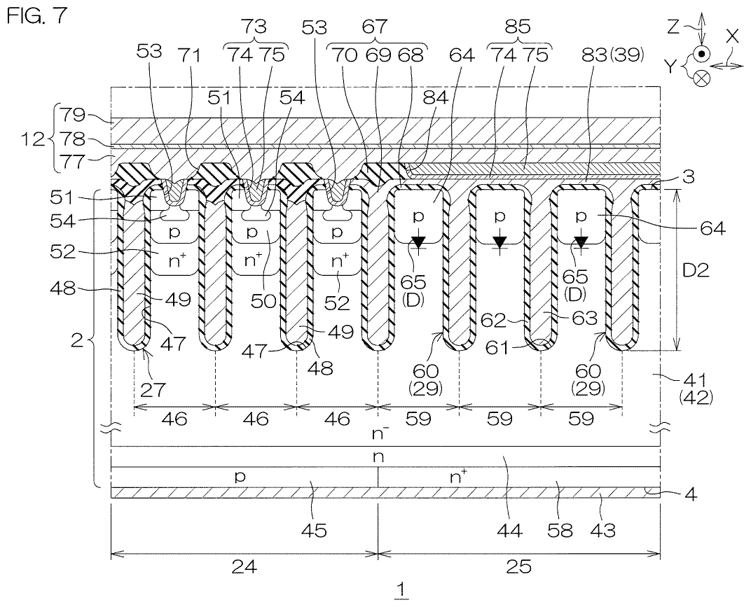

Next, another embodiment of the cross-sectional structure of the active region 18 will be described. FIG. 6 is a cross-sectional view taken along line VI-VI in FIG. 3. FIG. 7 is a cross-sectional view taken along line VII-VII in FIG. 3. A connection configuration between the third contact layer 40 and the emitter terminal electrode 12 and a connection configuration between the second contact layer 39 and the emitter terminal electrode 12 will be described with reference to FIGS. 6 and 7. In the following, structures corresponding to structures already described for the semiconductor device 1 shall be provided with the same reference signs and description thereof shall be omitted.

Referring to FIG. 6, the emitter potential electrode layer 57 of the emitter trench structure 28 has a lead-out electrode layer 80 led out from the emitter trench 55 onto the first principal surface 3. The lead-out electrode layer 80 is the third contact layer 40 in FIG. 3. The lead-out electrode layer 80 is specifically formed inside the interlayer insulating layer 67. The lead-out electrode layer 80 is led out onto the first insulating layer 68 and is interposed in a region between the first insulating layer 68 and the third insulating layer 70. The lead-out electrode layer 80 is electrically connected to the emitter terminal electrode 12. The emitter signal applied to the lead-out electrode layer 80 is transmitted to the emitter potential electrode layer 57 through the lead-out electrode layer 80.

The interlayer insulating layer 67 includes a first opening 81. The first opening 81 exposes the lead-out electrode layer 80 in the IGBT region 24. The first opening 81 is formed such that the opening width becomes narrow from the opening side toward the bottom wall side.

The semiconductor device 1 includes a first plug electrode 82 embedded in the first opening 81. The first plug electrode 82 is electrically connected to the lead-out electrode layer 80 in the first opening 81. The first plug electrode 82 has a structure corresponding to the emitter plug electrode 73. Description of the emitter plug electrode 73 applies to description concerning the first plug electrode 82. In the first plug electrode 82, structures corresponding to structures described for the emitter plug electrode 73 shall be provided with the same reference signs and description thereof shall be omitted.

The emitter terminal electrode 12 is electrically connected to the emitter potential electrode layer 57 through the first plug electrode 82 and the lead-out electrode layer 80 on the interlayer insulating layer 67.

Referring to FIG. 7, the cell separation electrode layer 63 of the cell separation structure 60 includes a lead-out electrode layer 83 led out from the cell separation trench 61 onto the first principal surface 3. The lead-out electrode layer 83 is the second contact layer 39 in FIG. 3. The lead-out electrode layer 83 is specifically formed inside the interlayer insulating layer 67. The lead-out electrode layer 83 is led out onto the first insulating layer 68 and is interposed in the region between the first insulating layer 68 and the third insulating layer 70. The lead-out electrode layer 83 is electrically connected to the emitter terminal electrode 12. The emitter signal applied to the lead-out electrode layer 83 is transmitted to the cell separation electrode layer 63 through the lead-out electrode layer 83.

The interlayer insulating layer 67 includes a second opening 84. The second opening 84 exposes the lead-out electrode layer 83 in the diode region 25. The second opening 84 is formed such that the opening width becomes narrow from the opening side toward the bottom wall side. The second opening 84 is formed in a band shape extending in the first direction X.

The semiconductor device 1 includes a second plug electrode 85 embedded in the second opening 84. The second plug electrode 85 is electrically connected to the lead-out electrode layer 83 in the second opening 84. The second plug electrode 85 has a structure corresponding to the emitter plug electrode 73. Description of the emitter plug electrode 73 applies to description concerning the second plug electrode 85. In the second plug electrode 85, structures corresponding to structures described for the emitter plug electrode 73 shall be provided with the same reference signs and description thereof shall be omitted.

The emitter terminal electrode 12 is electrically connected to the cell separation electrode layer 63 through the second plug electrode 85 and the lead-out electrode layer 83 on the interlayer insulating layer 67.

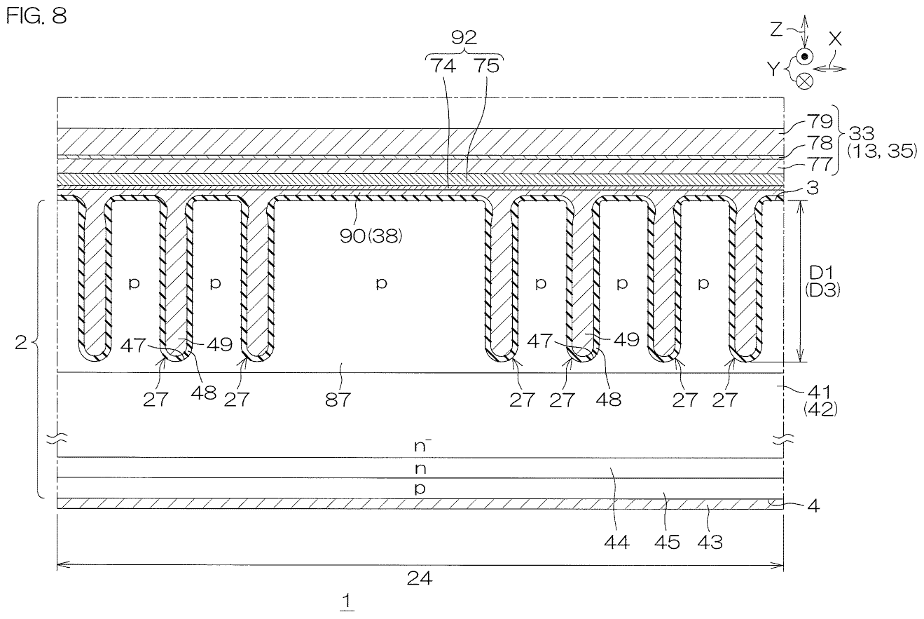

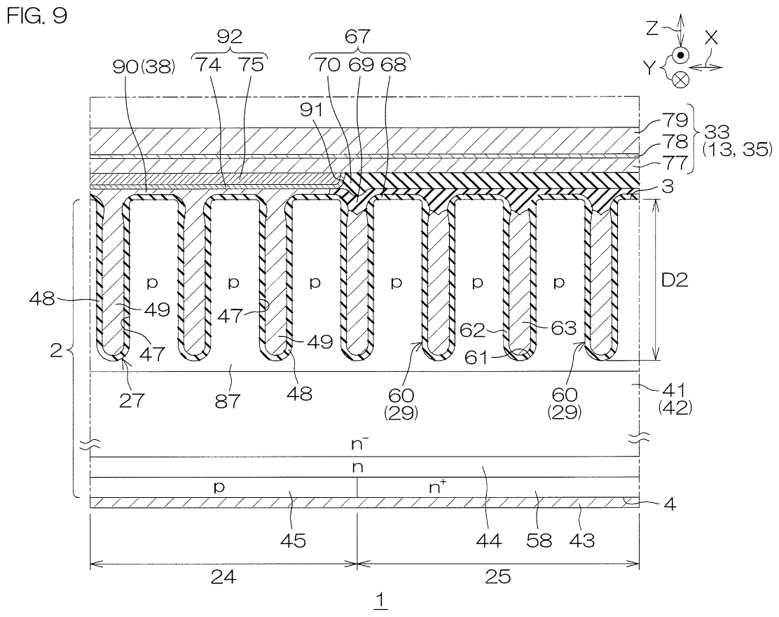

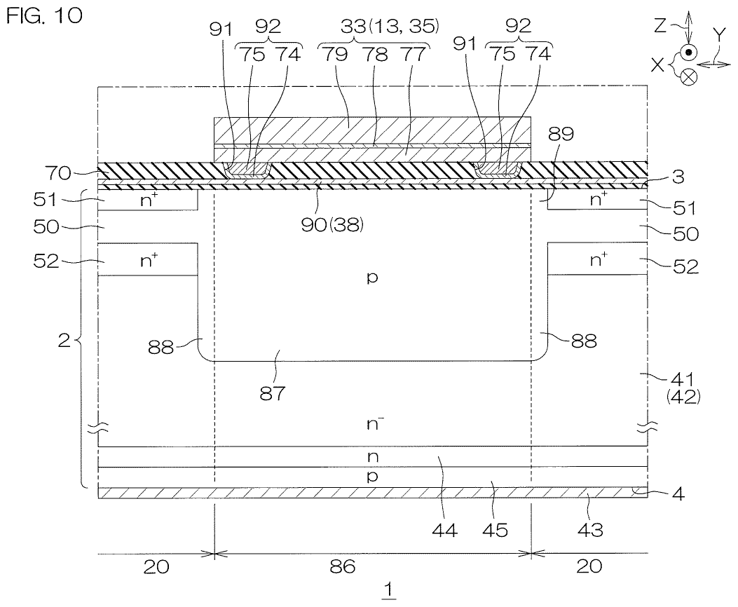

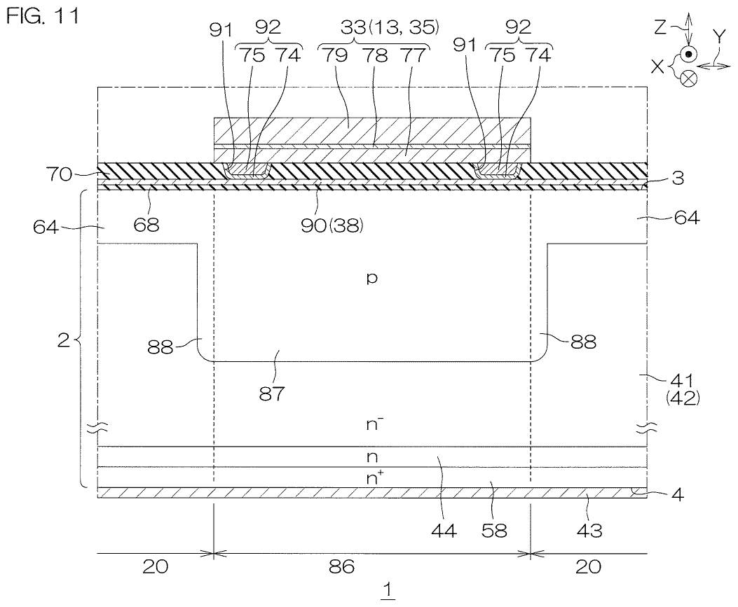

Next, another embodiment of the cross-sectional structure of the active region 18 will be described. FIG. 8 is a cross-sectional view taken along line VIII-VIII in FIG. 3. FIG. 9 is a cross-sectional view taken along line IX-IX in FIG. 3. FIG. 10 is a cross-sectional view taken along line X-X in FIG. 3. FIG. 11 is a cross-sectional view taken along line XI-XI in FIG. 3. A connection configuration between the first contact layer 38 and the gate extending electrode 33 (gate wiring 13) and a structure of the semiconductor chip 2 immediately below the gate extending electrode 33 will be described with reference to FIGS. 8 to 11. In the following, structures corresponding to structures already described for the semiconductor device 1 shall be provided with the same reference signs and description thereof shall be omitted.

Referring to FIGS. 8 to 11, the semiconductor device 1 includes a p type well region 87 formed in the surface layer portion of the first principal surface 3 in a region immediately below the gate extending electrode 33 (a boundary region 86 between the adjacent demarcated regions 20). In this embodiment, the well region 87 has a p type impurity concentration higher than that of the body region 50. As a matter of course, the well region 87 may have a p type impurity concentration lower than that of the body region 50.

The well region 87 is formed in a band shape extending in the first direction X along the boundary region 86 in plan view. The well region 87 is formed in a layered shape extending along the first principal surface 3 and is exposed from the first principal surface 3. Referring to FIG. 8, the well region 87 is formed in a region sandwiched by the plurality of trench gate structures 27 and a region sandwiched by the plurality of emitter trench structures 28. In addition, referring to FIG. 9, the well region 87 is formed in a region sandwiched by the plurality of cell separation structures 60.

The well region 87 is preferably formed deeper than the body region 50 and the anode region 64. The well region 87 is particularly preferably formed deeper than the plurality of trench gate structures 27, the plurality of emitter trench structures 28, and the plurality of cell separation structures 60.

Referring to FIGS. 8 and 9, the well region 87 has a portion covering bottom walls of the plurality of trench gate structures 27 and bottom walls of the plurality of emitter trench structures 28. The well region 87 crosses the plurality of trench gate structures 27 and the plurality of emitter trench structures 28 in the first direction X and collectively covers the bottom walls thereof.

Referring to FIG. 9, the well region 87 has a portion covering bottom walls of the plurality of cell separation structures 60. The well region 87 crosses the plurality of cell separation structures 60 in the first direction X and collectively covers the bottom walls thereof. In addition, the well region 87 crosses the plurality of trench gate structures 27 and the plurality of cell separation structures 60 in the first direction X and collectively covers the bottom walls thereof. Referring to FIG. 9, the well region 87 extends across a boundary portion between the IGBT region 24 and the diode region 25 in the first direction X.

Referring to FIGS. 10 and 11, the gate extending electrode 33 is crossed in the second direction Y. In this embodiment, the well region 87 has a width larger than the width of the boundary region 86 in the second direction Y. The well region 87 has a lead-out portion 88 led out from the boundary region 86 into the plurality of demarcated regions 20.

Referring to FIG. 10, the well region 87 is integrally continuous with the body region 50 of the IGBT region 24. The lead-out portion 88 of the well region 87 is connected to a side portion of the body region 50. The well region 87 has an upper protrusion portion 89 protruding further upward than an upper end of the body region 50 (a boundary between the body region 50 and the emitter region 51).

Referring to FIG. 11, the well region 87 is integrally continuous with the anode region 64 of the diode region 25. The lead-out portion 88 of the well region 87 is connected to a side portion of the anode region 64. The well region 87 has an upper end at the same height position as the upper end of the anode region 64 (first principal surface 3).

Referring to FIGS. 8 to 11, the gate electrode layer 49 of the trench gate structure 27 includes a lead-out electrode layer 90 led out from the gate trench 47 onto the first principal surface 3. The lead-out electrode layer 90 is the first contact layer 38 (first electrode layer 34) in FIG. 3. The lead-out electrode layer 90 is specifically formed inside the interlayer insulating layer 67. The lead-out electrode layer 90 is led out onto the first insulating layer 68 and is interposed in the region between the first insulating layer 68 and the third insulating layer 70. The lead-out electrode layer 90 is electrically connected to the gate extending electrode 33. The gate signal applied to the lead-out electrode layer 90 is transmitted to the gate electrode layer 49 through the lead-out electrode layer 90.

Referring to FIGS. 9 to 11, the interlayer insulating layer 67 includes a gate opening 91. The gate opening 91 exposes the lead-out electrode layer 90 in the IGBT region 24. The gate opening 91 is formed such that the opening width becomes narrow from the opening side toward the bottom wall side. In this embodiment, a pair of gate openings 91 are formed along the gate extending electrode 33. Referring to FIG. 9, each gate opening 91 extends in a band shape in the first direction X and has an end portion immediately above the boundary portion between the IGBT region 24 and the diode region 25.

The semiconductor device 1 includes a gate plug electrode 92 embedded in the gate opening 91. The gate plug electrode 92 is electrically connected to the lead-out electrode layer 90 in the gate opening 91. The gate plug electrode 92 has a structure corresponding to the emitter plug electrode 73. Description of the emitter plug electrode 73 applies to description concerning the gate plug electrode 92. In the gate plug electrode 92, structures corresponding to structures described for the emitter plug electrode 73 shall be provided with the same reference signs and description thereof shall be omitted.

The gate extending electrode 33 is electrically connected to the gate electrode layer 49 through the gate plug electrode 92 and the lead-out electrode layer 90 on the interlayer insulating layer 67. The second electrode layer 35 of the gate extending electrode 33 has a structure corresponding to the emitter terminal electrode 12. Description of the emitter terminal electrode 12 applies to description concerning the second electrode layer 35 of the gate extending electrode 33. In the second electrode layer 35 of the gate extending electrode 33, structures corresponding to structures described for the emitter terminal electrode 12 shall be provided with the same reference signs and description thereof shall be omitted.

As described above, according to the structures illustrated in FIGS. 3 to 11, the plurality of diode-side trench structures 29 are formed in stripes as a whole. The plurality of diode-side trench structures 29 cross immediately below the gate wiring 13 from one side to the other side in the second direction Y. That is, the plurality of diode-side trench structures 29 are not separated for each of the demarcated regions 20. As a result, the number of the terminal portions 32 of the plurality of diode-side trench structures 29 can be reduced. In this embodiment, the terminal portions 32 of the plurality of diode-side trench structures 29 are selectively formed only in the outer peripheral region 19.

Since the terminal portions 32 of the plurality of diode-side trench structures 29 each have a round shape, shape abnormality is more likely to occur due to process variation as compared with the stripe shape. Therefore, dielectric breakdown at the terminal portions 32 can be suppressed by reducing the number of the terminal portions 32 of the plurality of diode-side trench structures 29. As a result, ESD (Electro-Static Discharge) resistance of the semiconductor device 1 can be improved.

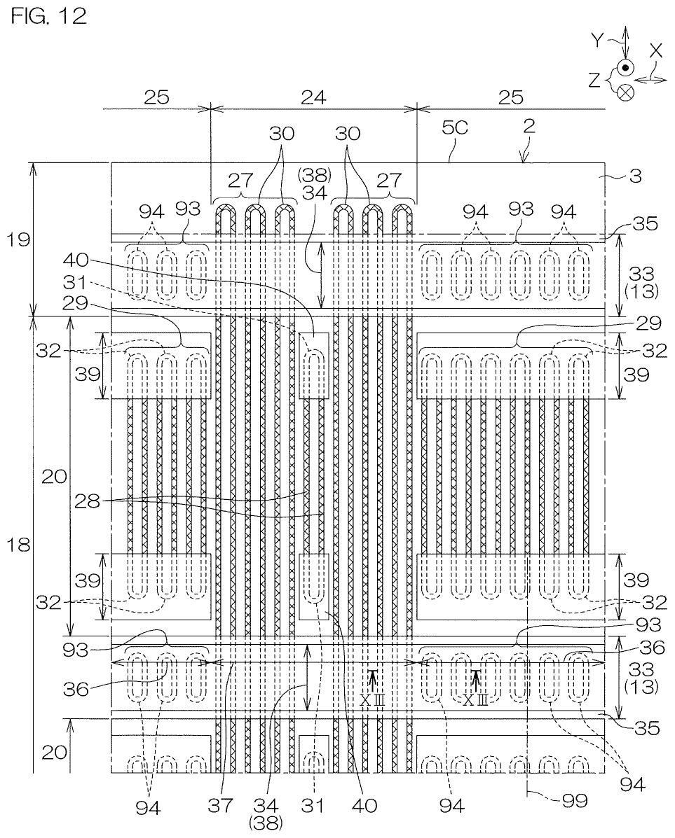

Next, another embodiment of the planar structure of the active region 18 will be described. FIG. 12 is an enlarged view of a portion surrounded by XII in FIG. 2, and illustrates a portion of the plurality of IGBT regions 24 and the plurality of diode regions 25. The planar structure of the IGBT region 24 and the diode region 25 described below may be applied to all the IGBT regions 24 and all the diode regions 25 of the semiconductor chip 2, or may be selectively applied to some of the IGBT regions 24 and the diode regions 25. That is, the planar structure described below is a structure applicable to at least one IGBT region 24 and one diode region 25.

In the diode region 25 illustrated in FIG. 12, the plurality of diode-side trench structures 29 do not cross the gate wiring 13, and have the terminal portion 32 inside the diode region 25 separated from the gate wiring 13 in the second direction Y. The second contact layer 39 collectively covers the terminal portions 32 of the plurality of diode-side trench structures 29. The second contact layer 39 is electrically connected to the diode-side trench structure 29 through the terminal portion 32.

The semiconductor device 1 includes a plurality of gate auxiliary trench structures 93 formed in the first principal surface 3. The plurality of gate auxiliary trench structures 93 are formed immediately below the gate extending electrode 33, and are covered with the gate extending electrode 33 in plan view. The plurality of gate auxiliary trench structures 93 are trench structures elongated along the second direction Y.

In FIG. 12, the plurality of gate auxiliary trench structures 93 are a plurality of elliptical trench structures whose major axis direction coincides with the second direction Y. The plurality of gate auxiliary trench structures 93 may each be formed in a band shape extending along the second direction Y in plan view. The plurality of gate auxiliary trench structures 93 are formed in stripes as a whole. In the plurality of gate auxiliary trench structures 93, the gate auxiliary trench structure 93 has a terminal portion 94 on each of one side and the other side in the second direction Y.

One each of the terminal portion 94 of the gate auxiliary trench structure 93 is formed for a pair of gate auxiliary trench structures 93. The terminal portion 94 connects the adjacent gate auxiliary trench structures 93 in a region immediately below the gate extending electrode 33 (boundary region 86 in FIGS. 10 and 11). The terminal portion 94 is formed in a round shape in plan view.

In addition, the diode-side trench structure 29 and the gate auxiliary trench structure 93 are formed on the same virtual straight line 99 (in FIG. 12, a line indicated by an alternate long and short dashed line) extending along the second direction Y. Therefore, the gate auxiliary trench structure 93 may be a trench structure formed on an extension line in the second direction Y of the diode-side trench structure 29.

The first electrode layer 34 of the gate extending electrode 33 is formed in a band shape that extends such as to continuously cross the plurality of IGBT regions 24 and the plurality of diode regions 25 alternately arrayed. The first electrode layer 34 has a band shape having a constant width in the second direction Y. Unlike the structure in FIG. 3, the first electrode layer 34 is disposed immediately below the second electrode layer 35 in both the non-contact section 36 and the contact section 37. As a result, the first electrode layer 34 collectively covers the plurality of trench gate structures 27 and the plurality of gate auxiliary trench structures 93. In this embodiment, the entire gate auxiliary trench structure 93 from one end to the other end in the second direction Y is covered with the first electrode layer 34.

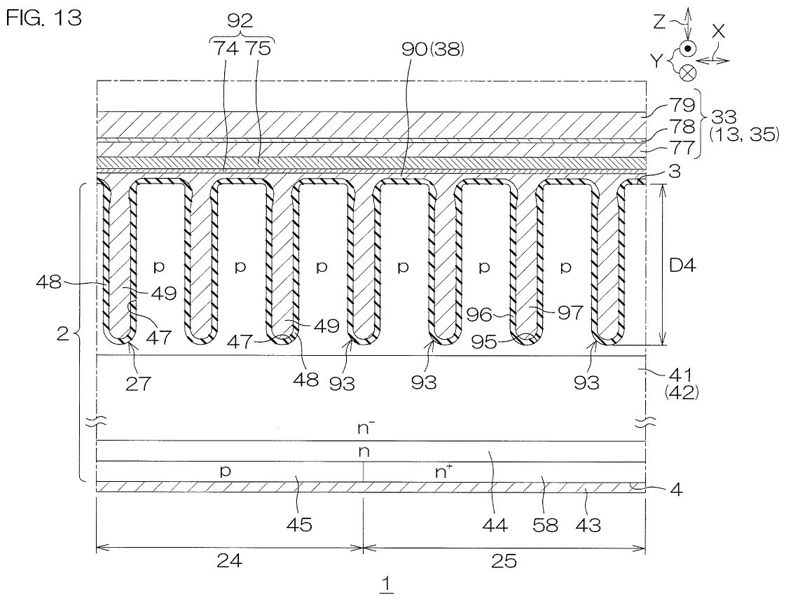

Next, a cross-sectional structure of the gate auxiliary trench structure 93 will be described. FIG. 13 is a cross-sectional view taken along line XIII-XIII in FIG. 12. In the following, structures corresponding to structures already described for the semiconductor device 1 shall be provided with the same reference signs and description thereof shall be omitted.

The gate auxiliary trench structure 93 includes a gate auxiliary trench 95, a gate auxiliary insulating layer 96, and a gate auxiliary electrode layer 97. The gate auxiliary trench 95 is formed in the first principal surface 3 of the semiconductor chip 2. The gate auxiliary trench 95 includes a side wall and a bottom wall. The side wall of the gate auxiliary trench 95 may be formed perpendicularly to the first principal surface 3.

The side wall of the gate auxiliary trench 95 may be inclined downward from the first principal surface 3 toward the bottom wall. The gate auxiliary trench 95 may be formed in a tapered shape in which the opening area on the opening side is larger than the bottom surface area. The well region 87 is exposed from the side wall of the gate auxiliary trench 95. The bottom wall of the gate auxiliary trench 95 may be formed in parallel with the first principal surface 3. The bottom wall of the gate auxiliary trench 95 may be formed in a curved shape toward the second principal surface 4. The gate auxiliary trench 95 includes a bottom wall edge portion. The bottom wall edge portion connects the side wall and the bottom wall of the gate auxiliary trench 95. The bottom wall edge portion may be formed in a curved shape toward the second principal surface 4 of the semiconductor chip 2.

A depth D4 of the gate auxiliary trench 95 may be 2 μm or more and 10 μm or less. The depth D4 of the gate auxiliary trench 95 may be 2 μm or more and 3 μm or less, 3 μm or more and 4 μm or less, 4 μm or more and 5 μm or less, 5 μm or more and 6 μm or less, 6 μm or more and 7 μm or less, 8 μm or more and 9 μm or less, or 9 μm or more and 10 μm or less. The depth D4 of the gate auxiliary trench 95 may be equal to the depth D1 of the gate trench 47.

The width of the gate auxiliary trench 95 may be 0.5 μm or more and 3 μm or less. The width of the gate auxiliary trench 95 is a width of the gate auxiliary trench 95 in the first direction X. The width of the gate auxiliary trench 95 may be 0.5 μm or more and 1 μm or less, 1 μm or more and 1.5 μm or less, 1.5 μm or more and 2 μm or less, 2 μm or more and 2.5 μm or less, or 2.5 μm or more and 3 μm or less. The width of the gate auxiliary trench 95 may be equal to the width of the gate trench 47.

The gate auxiliary insulating layer 96 is formed in a film shape along an inner wall of the gate auxiliary trench 95. The gate auxiliary insulating layer 96 demarcates a recess space in the gate auxiliary trench 95. In this embodiment, the gate auxiliary insulating layer 96 includes a silicon oxide film. The gate auxiliary insulating layer 96 may include a silicon nitride film instead of or in addition to the silicon oxide film.

The gate auxiliary electrode layer 97 is embedded in the gate auxiliary trench 95 across the gate auxiliary insulating layer 96. Specifically, the gate auxiliary electrode layer 97 is embedded in the recess space demarcated by the gate auxiliary insulating layer 96 in the gate auxiliary trench 95. The gate auxiliary electrode layer 97 may contain a conductive polysilicon. The gate auxiliary electrode layer 97 is controlled to a gate potential.

The lead-out electrode layer 90 led out from the gate trench 47 onto the first principal surface 3 is integrally connected to the gate auxiliary electrode layer 97. That is, the lead-out electrode layer 90 is integrally led out from the gate electrode layer 49 and the gate auxiliary electrode layer 97 onto the first principal surface 3, and collectively covers the gate trench 47 and the gate auxiliary trench 95.

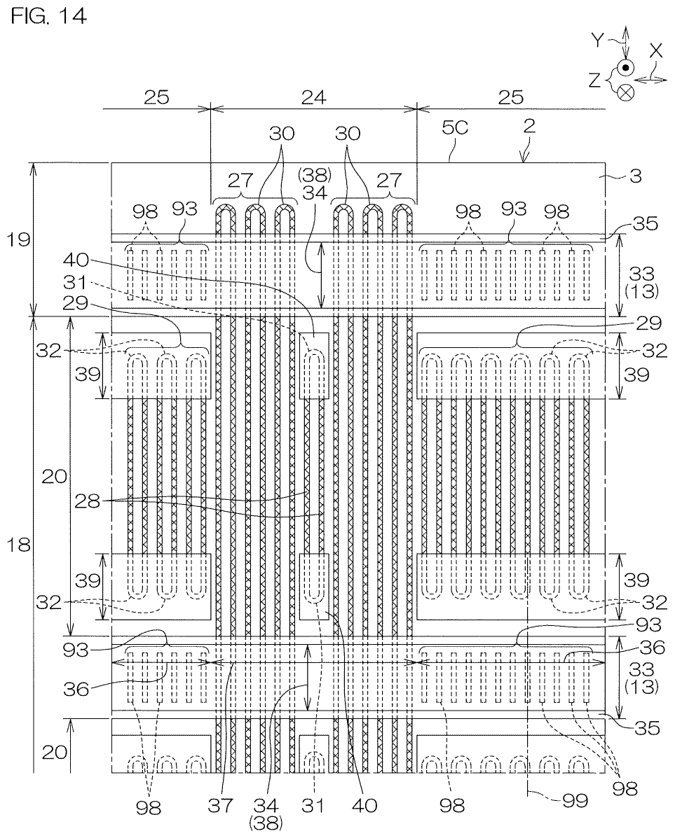

Next, variations of the pattern of the gate auxiliary trench structure 93 will be described with reference to FIGS. 14 to 16.

First, referring to FIG. 14, each of the plurality of gate auxiliary trench structures 93 may be formed in an independent band shape. Each gate auxiliary trench structure 93 is a band-shaped trench structure whose length direction coincides with the second direction Y. In this embodiment, a terminal portion 98 of each gate auxiliary trench structure 93 is disposed further inward than both side edges of the first electrode layer 34 in the second direction Y, and is covered with the first electrode layer 34.

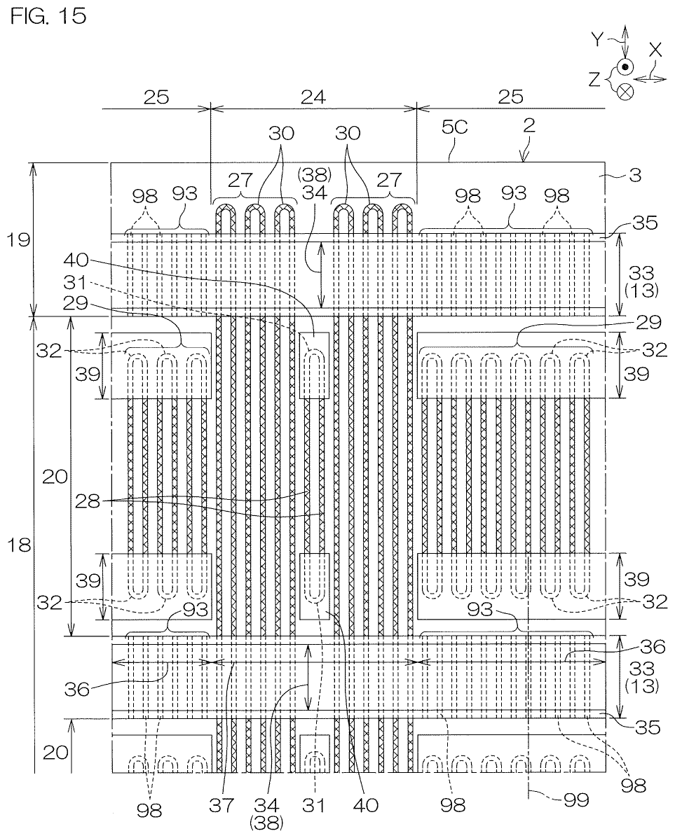

Next, referring to FIG. 15, each of the plurality of gate auxiliary trench structures 93 may be formed in an independent band shape. Each gate auxiliary trench structure 93 is a band-shaped trench structure whose length direction coincides with the second direction Y. In this embodiment, the terminal portion 98 of each gate auxiliary trench structure 93 protrudes further outward than both side edges of the first electrode layer 34 in the second direction Y, and is exposed from the first electrode layer 34.

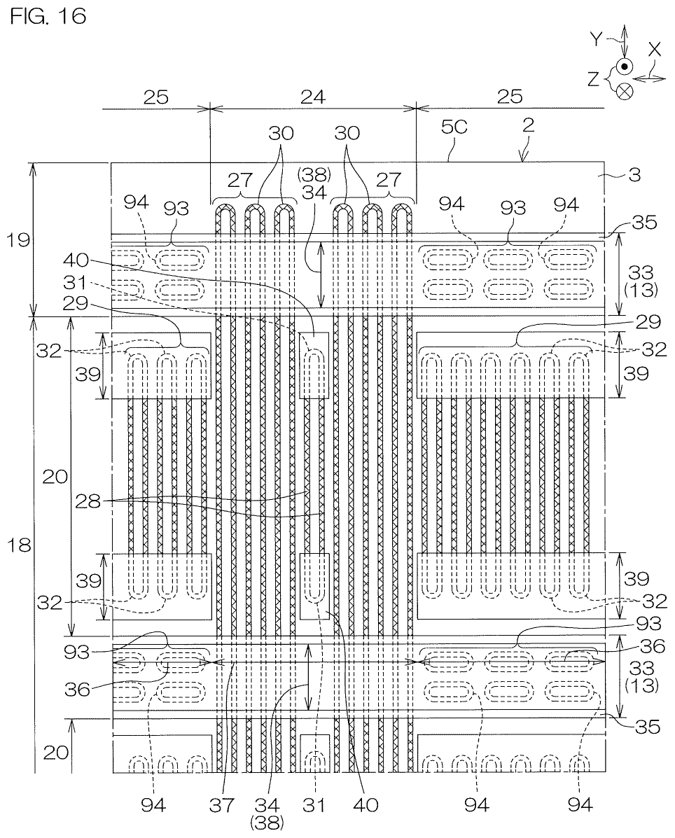

Next, referring to FIG. 16, the plurality of gate auxiliary trench structures 93 are trench structures elongated along the first direction X. FIG. 16 illustrates a structure in which the elliptical trench structure in FIG. 12 is rotated by 90°, but as a matter of course, a structure in which the band-shaped trench structure in FIGS. 14 and 15 is rotated by 90° may be adopted.

As described above, according to the structures illustrated in FIGS. 12 to 16, the plurality of gate auxiliary trench structures 93 controlled to the gate potential are formed. As a result, since the gate capacitance can be increased, the ESD resistance of the gate can be improved. In addition, the plurality of gate auxiliary trench structures 93 are disposed in an empty space immediately below the gate extending electrode 33 sandwiched between the plurality of diode-side trench structures 29. Therefore, an increase in chip area and an increase in gate trench density can be avoided due to the gate auxiliary trench structure 93. As a result, it is possible to suppress an increase in chip cost and an increase in process difficulty.

In addition, as illustrated in FIGS. 12, 14, and 15, when the plurality of gate auxiliary trench structures 93 are long trenches along the second direction Y, even if positional displacement occurs in the gate extending electrode 33 in the second direction Y, the gate extending electrode 33 can be reliably connected to the gate auxiliary trench structure 93.

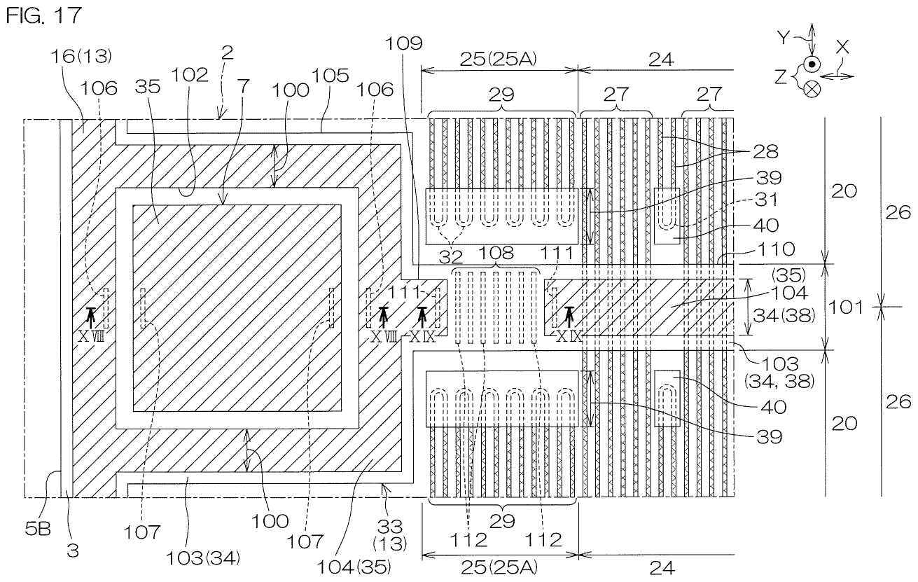

Next, one embodiment of the planar structure in the vicinity of the gate terminal electrode 7 will be described. FIG. 17 is an enlarged view of a portion surrounded by XVII in FIG. 2, and illustrates a portion of the plurality of IGBT regions 24 and the plurality of diode regions 25. The planar structure of the IGBT region 24 and the diode region 25 described below may be applied to all the IGBT regions 24 and all the diode regions 25 of the semiconductor chip 2, or may be selectively applied to some of the IGBT regions 24 and the diode regions 25. That is, the planar structure described below is a structure applicable to at least one IGBT region 24 and one diode region 25.

In this embodiment, the first end portion (end portion on the side surface 5B side) of the RC-IGBT array 26 is formed by the diode region 25. The diode region 25 is a region adjacent to the plurality of terminal electrodes 7 to 11 and may be referred to as a pad adjacent diode region 25A. The pad adjacent diode region 25A is adjacent to the gate terminal electrode 7 in the first direction X. The phrase “adjacent to the gate terminal electrode 7” may mean that no other diode region 25 or IGBT region 24 is interposed between the gate terminal electrode 7 and the pad adjacent diode region 25A in the first direction X.

In the pad adjacent diode region 25A, the plurality of diode-side trench structures 29 do not cross the gate wiring 13, and have the terminal portion 32 inside the diode region 25 separated from the gate wiring 13 in the second direction Y. The second contact layer 39 collectively covers the terminal portions 32 of the plurality of diode-side trench structures 29. The second contact layer 39 is electrically connected to the diode-side trench structure 29 through the terminal portion 32.

The gate extending electrode 33 includes an annular peripheral portion 100 surrounding the gate terminal electrode 7 and an extending portion 101 extending in a band shape in the first direction X from the peripheral portion 100.

The peripheral portion 100 surrounds the entire periphery of the gate terminal electrode 7, but may be partially separated. An end portion of the peripheral portion 100 on the side surface 5B side is integrally continuous with the first portion 16 of the gate wiring 13. An annular gap region 102 is formed between the peripheral portion 100 and the gate terminal electrode 7.

The extending portion 101 extends in the first direction X from an end portion opposite to the end portion of the peripheral portion 100 on the side surface 5B side. The extending portion 101 extends in a band shape in the first direction X.

In FIG. 17, the peripheral portion 100 and the extending portion 101 are formed by a laminated structure of a resistance layer 103 and a wiring layer 104. The lower resistance layer 103 of the laminated structure is a open region, and the upper wiring layer 104 is a hatched region. The resistance layer 103 also serves as the first electrode layer 34 and the first contact layer 38 described above. The wiring layer 104 also serves as the second electrode layer 35 described above.

A portion of the laminated structure of the resistance layer 103 and the wiring layer 104 may constitute the gate terminal electrode 7 in addition to constituting the gate extending electrode 33. In FIG. 17, a portion of the resistance layer 103 forms a pad support layer 105 having an island shape, and the peripheral portion 100 and the second electrode layer 35 constituting the gate terminal electrode 7 are formed on the pad support layer 105 independently of each other.

The second electrode layer 35 of the peripheral portion 100 is connected to the pad support layer 105 through a peripheral contact 106. In this embodiment, a pair of peripheral contacts 106 opposing each other across the gate terminal electrode 7 in the first direction X are formed. One each of the pair of peripheral contacts 106 is formed at the end portion of the peripheral portion 100 on the side surface 5B side and at the end portion on the opposite side.

The second electrode layer 35 of the gate terminal electrode 7 is connected to the pad support layer 105 through a pad contact 107. In this embodiment, a pair of pad contacts 107 are formed adjacent to the peripheral contact 106 in the first direction X. One each of the pair of pad contacts 107 is formed at a position adjacent to each of the peripheral contacts 106.

The semiconductor device 1 includes a gate resistor 108 adjacent to the gate terminal electrode 7. In the gate extending electrode 33, the gate resistor 108 is selectively formed in a portion crossing the diode region 25 while avoiding a portion immediately above the trench gate structure 27. In this embodiment, the gate resistor 108 is formed at a position adjacent to the terminal portion 32 of the diode-side trench structure 29 in the second direction Y in the extending portion 101. More specifically, the gate resistor 108 is formed in a region sandwiched by the plurality of diode-side trench structures 29 opposing each other across the gate extending electrode 33.

In a region adjacent to the terminal portion 32, the wiring layer 104 of the gate extending electrode 33 (extending portion 101) is separated into one side and the other side in first direction X. The gate resistor 108 is formed by a portion of the resistance layer 103 sandwiched between the separated wiring layers 104.

The extending portion 101 includes a first extending portion 109 close to the gate terminal electrode 7 and a second extending portion 110 on the opposite side. Each of the first extending portion 109 and the second extending portion 110 is connected to the resistance layer 103 through a resistance contact 111.

The gate resistor 108 is disposed between the first extending portion 109 and the second extending portion 110. The gate resistor 108 is formed in a band shape in plan view extending in the first direction X and having a constant width.

The gate resistor 108 may further include a plurality of trench resistor structures 112. The plurality of trench resistor structures 112 are formed in stripes elongated in the second direction Y between the first extending portion 109 and the second extending portion 110. Each trench resistor structure 112 is formed in a band shape in plan view which is long in a direction crossing the gate extending electrode 33.

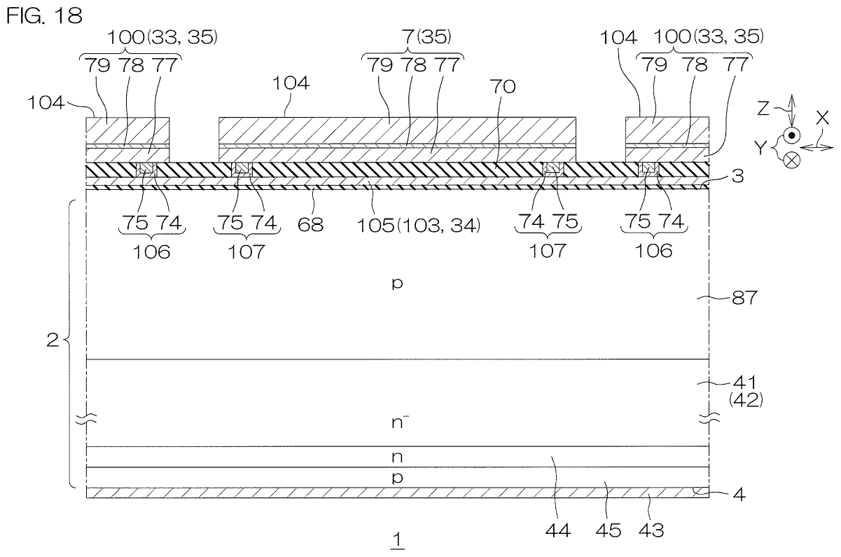

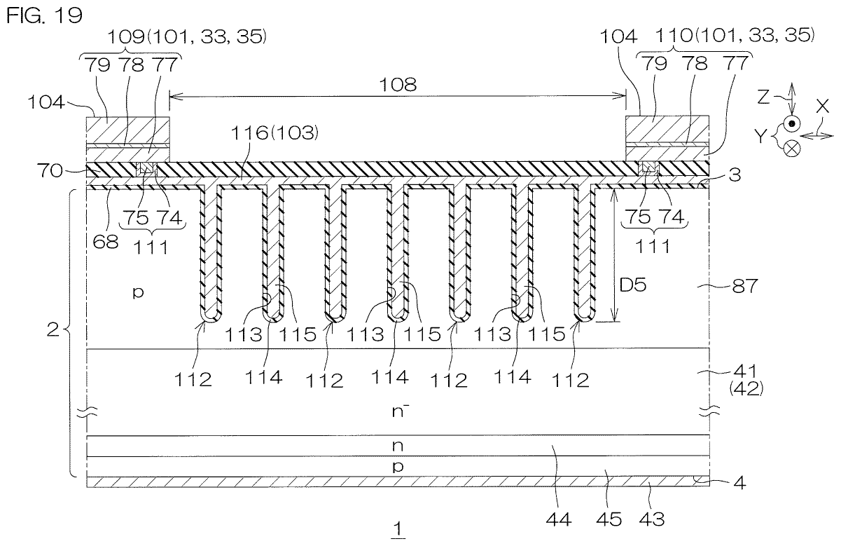

Next, a cross-sectional structure in FIG. 17 will be described. FIG. 18 is a cross-sectional view taken along line XVIII-XVIII in FIG. 17. FIG. 19 is a cross-sectional view taken along line XIX-XIX in FIG. 17.

First, a cross-sectional structure of the gate terminal electrode 7 will be described with reference to FIG. 18. The well region 87 spreads immediately below the gate terminal electrode 7. In the well region 87, the pad support layer 105 (resistance layer 103, first electrode layer 34) is formed through the first insulating layer 68. The pad support layer 105 is covered with the third insulating layer 70.

The peripheral contact 106 and the pad contact 107 are embedded in the third insulating layer 70. The peripheral contact 106 and the pad contact 107 may be referred to as a peripheral plug electrode and a pad plug electrode, respectively. The peripheral contact 106 and the pad contact 107 have a structure corresponding to the emitter plug electrode 73. Description of the emitter plug electrode 73 applies to description concerning the peripheral contact 106 and the pad contact 107. In the peripheral contact 106 and the pad contact 107, structures corresponding to structures described for the emitter plug electrode 73 shall be provided with the same reference signs and description thereof shall be omitted.

The gate terminal electrode 7 and the peripheral portion 100 are formed on the third insulating layer 70. The gate terminal electrode 7 and the peripheral portion 100 are electrically connected to each other through the pad contact 107, the pad support layer 105, and the peripheral contact 106.

Next, a cross-sectional structure of the gate resistor 108 will be described with reference to FIG. 19. The trench resistor structure 112 is formed in the first principal surface 3.

The trench resistor structure 112 includes a resistance trench 113, a resistance insulating layer 114, and a resistance electrode layer 115. The resistance trench 113 is formed in the first principal surface 3 of the semiconductor chip 2. The resistance trench 113 includes a side wall and a bottom wall. The side wall of the resistance trench 113 may be formed perpendicularly to the first principal surface 3.

The side wall of the resistance trench 113 may be inclined downward from the first principal surface 3 toward the bottom wall. The resistance trench 113 may be formed in a tapered shape in which the opening area on the opening side is larger than the bottom surface area. The well region 87 is exposed from the side wall of the resistance trench 113. The bottom wall of the resistance trench 113 may be formed in parallel with the first principal surface 3. The bottom wall of the resistance trench 113 may be formed in a curved shape toward the second principal surface 4. The resistance trench 113 includes a bottom wall edge portion. The bottom wall edge portion connects the side wall and the bottom wall of the resistance trench 113. The bottom wall edge portion may be formed in a curved shape toward the second principal surface 4 of the semiconductor chip 2.

A depth D5 of the resistance trench 113 may be 2 μm or more and 10 μm or less. The depth D5 of the resistance trench 113 may be 2 μm or more and 3 μm or less, 3 μm or more and 4 μm or less, 4 μm or more and 5 μm or less, 5 μm or more and 6 μm or less, 6 μm or more and 7 μm or less, 8 μm or more and 9 μm or less, or 9 μm or more and 10 μm or less. The depth D5 of the resistance trench 113 may be equal to the depth D1 of the gate trench 47.

The width of the resistance trench 113 may be 0.5 μm or more and 3 μm or less. The width of the resistance trench 113 is a width of the resistance trench 113 in the first direction X. The width of the resistance trench 113 may be 0.5 μm or more and 1 μm or less, 1 μm or more and 1.5 μm or less, 1.5 μm or more and 2 μm or less, 2 μm or more and 2.5 μm or less, or 2.5 μm or more and 3 μm or less. The width of the resistance trench 113 may be equal to the width of the gate trench 47.

The resistance insulating layer 114 is formed in a film shape along an inner wall of the resistance trench 113. The resistance insulating layer 114 demarcates a recess space in the resistance trench 113. In this embodiment, the resistance insulating layer 114 includes a silicon oxide film. The resistance insulating layer 114 may include a silicon nitride film instead of or in addition to the silicon oxide film.

The resistance electrode layer 115 is embedded in the resistance trench 113 across the resistance insulating layer 114. Specifically, the resistance electrode layer 115 is embedded in the recess space demarcated by the resistance insulating layer 114 in the resistance trench 113. The resistance electrode layer 115 may contain a conductive polysilicon. The resistance electrode layer 115 is controlled to a gate potential.

The gate resistor 108 includes a lead-out resistance layer 116 led out from the resistance trench 113 onto the first principal surface 3. The lead-out resistance layer 116 is integrally connected to the resistance electrode layer 115. That is, the lead-out resistance layer 116 is integrally led out from the resistance electrode layer 115 onto the first principal surface 3, and collectively covers the plurality of resistance trenches 113. The pad support layer 105 is covered with the third insulating layer 70.

The resistance contact 111 is embedded in the third insulating layer 70. The resistance contact 111 may be referred to as a resistance plug electrode. The resistance contact 111 has a structure corresponding to the emitter plug electrode 73. Description of the emitter plug electrode 73 applies to description concerning the resistance contact 111. In the resistance contact 111, structures corresponding to structures described for the emitter plug electrode 73 shall be provided with the same reference signs and description thereof shall be omitted.

The first extending portion 109 and the second extending portion 110 are formed on the third insulating layer 70. The first extending portion 109 and the second extending portion 110 are electrically connected to each other through the resistance contact 111, the lead-out resistance layer 116, and the resistance electrode layer 115.

A portion of the resistance layer 103 where the first extending portion 109 and the second extending portion 110 are laminated is short-circuited by the first extending portion 109 and the second extending portion 110 formed of the wiring layer 104 having a lower resistance than the resistance layer 103. Thus, a portion of the resistance layer 103 exposed between the first extending portion 109 and the second extending portion 110 forms the gate resistor 108.

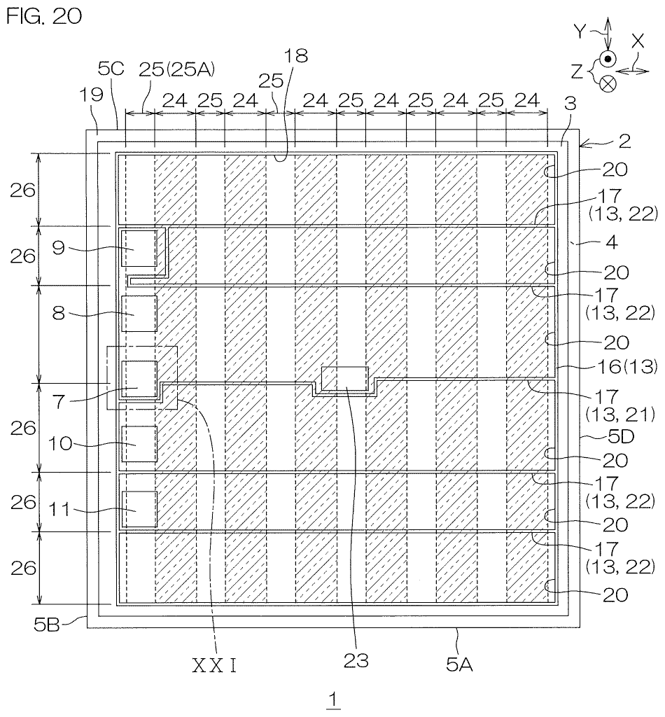

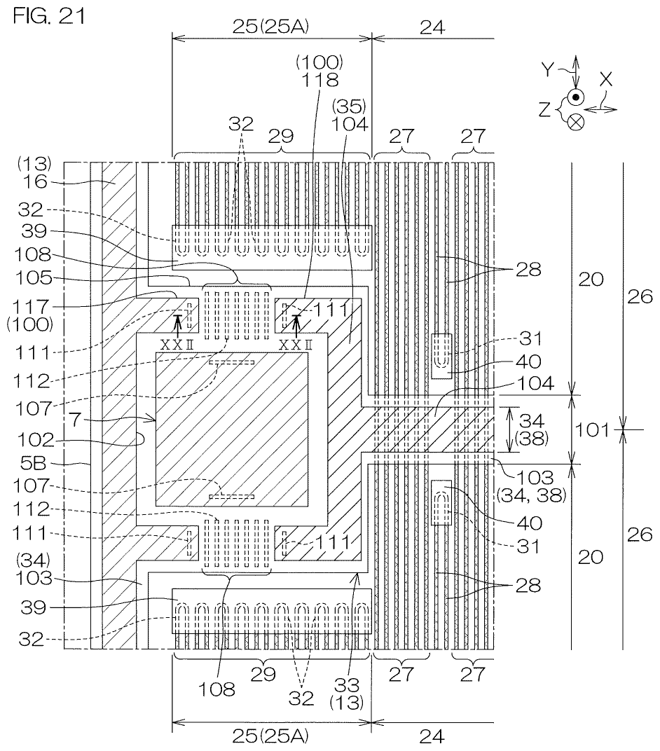

FIG. 20 is a view illustrating a modification example of an arrangement pattern of the IGBT region 24 and the diode region 25. FIG. 21 is an enlarged view of a portion surrounded by XXI in FIG. 20.

Referring to FIGS. 20 and 21, the first end portion (end portion on the side surface 5B side) of the RC-IGBT array 26 is formed by the diode region 25. The diode region 25 is a region adjacent to the plurality of terminal electrodes 7 to 11 and may be referred to as a pad adjacent diode region 25A. The pad adjacent diode region 25A is adjacent to the gate terminal electrode 7 in the second direction Y.

In the pad adjacent diode region 25A, the plurality of diode-side trench structures 29 do not cross the gate wiring 13, and have the terminal portion 32 inside the diode region 25 separated from the gate wiring 13 in the second direction Y. The second contact layer 39 collectively covers the terminal portions 32 of the plurality of diode-side trench structures 29. The second contact layer 39 is electrically connected to the diode-side trench structure 29 through the terminal portion 32. The terminal portions 32 of the plurality of diode-side trench structures 29 oppose each other in the second direction Y across the gate terminal electrode 7 and the peripheral portion 100.

In the gate extending electrode 33, the gate resistor 108 is selectively formed in a portion crossing the diode region 25 while avoiding a portion immediately above the trench gate structure 27. In this embodiment, the gate resistor 108 is formed at a position adjacent to the terminal portion 32 of the diode-side trench structure 29 in the second direction Y in the peripheral portion 100. More specifically, the gate resistor 108 is formed in a region sandwiched by the plurality of diode-side trench structures 29 opposing each other across the gate terminal electrode 7 and the peripheral portion 100. A pair of gate resistors 108 oppose each other in the second direction Y across the gate terminal electrode 7.

In a region adjacent to the terminal portion 32, the wiring layer 104 of the gate extending electrode 33 (peripheral portion 100) is separated into one side and the other side in the first direction X. The gate resistor 108 is formed by a portion of the resistance layer 103 (pad support layer 105) sandwiched between the separated wiring layers 104.

The peripheral portion 100 includes a first peripheral portion 117 continuous with the first portion 16 of the gate wiring 13 and a second peripheral portion 118 on the opposite side. The first peripheral portion 117 and the second peripheral portion 118 are each connected to the resistance layer 103 through the resistance contact 111.

The gate resistor 108 is disposed between the first peripheral portion 117 and the second peripheral portion 118. The gate resistor 108 is formed in a band shape in plan view extending in the first direction X and having a constant width.

The gate resistor 108 may further include a plurality of trench resistor structures 112. The plurality of trench resistor structures 112 are formed in stripes elongated in the second direction Y between the first peripheral portion 117 and the second peripheral portion 118. Each trench resistor structure 112 is formed in a band shape in plan view which is long in a direction crossing the gate extending electrode 33.

As described above, according to the structures illustrated in FIGS. 17 to 21, the gate resistor 108 is formed in the gate extending electrode 33. The gate resistor 108 constitutes a gate resistor for the gate of the IGBT. For example, the gate resistor 108 is effective in suppressing oscillation (noise) caused by parasitic inductance at turn-off. In addition, the gate resistor 108 is disposed in the empty space immediately below the gate extending electrode 33 sandwiched between the plurality of diode-side trench structures 29. Therefore, an increase in the chip area can be avoided due to the gate resistor 108. Therefore, it is possible to provide the semiconductor device 1 including the gate resistor 108 without impairing an effective area of the IGBT region 24.

Although preferred embodiments of the present disclosure have been described above, the present disclosure can be implemented in yet other embodiments.

For example, in each of the preferred embodiments described above, a structure in which the conductivity types of the respective semiconductor portions are inverted may be adopted. That is, a p type portion may be formed to be of an n type and an n type portion may be formed to be of a p type.

Thus, the preferred embodiments of the present disclosure in all respects are illustrative and not to be interpreted to be restrictive and are intended to include modifications in all respects.

The following appended features can be extracted from the descriptions in this Description and the drawings. Hereinafter, the alphanumeric characters in parentheses represent the corresponding components, etc., in the preferred embodiments described above, but are not intended to limit the scope of each clause to the preferred embodiments.
[Clause 1-1]
A semiconductor device (1) including:
a chip (2) which has a first principal surface (3) and a second principal surface (4);
an insulating layer (67) which covers the first principal surface (3);
an extending electrode (33) which extends in a region on the first principal surface (3) in a first direction (X), the extending electrode (33) which includes a first electrode layer (34) formed between the insulating layer (67) and the first principal surface (3) and a second electrode layer (35) formed on the insulating layer (67) and electrically connected to the first electrode layer (34);
a first element region (24) which includes an element electrically connected to the extending electrode (33);
a second element region (25) which is adjacent to the first element region (24) in the first direction (X) and is formed on one side and the other side across the extending electrode (33) in a second direction (Y) intersecting the first direction (X); and
a second trench electrode structure (29) which is formed in the first principal surface (3) of the chip (2), crosses the extending electrode (33), and extends across the plurality of second element regions (25) adjacent to each other across the extending electrode (33),
wherein the extending electrode (33) does not include the first electrode layer (34) and selectively includes the second electrode layer (35) immediately above the second trench electrode structure (29).
According to this configuration, the second trench electrode structure (29) crosses the extending electrode (33) and extends across the plurality of second element regions (25) adjacent to each other across the extending electrode (33). That is, the second trench electrode structure (29) is not separated for each second element region (25). As a result, the number of terminal portions of the second trench electrode structure (29) can be reduced. For example, when the terminal portion of the second trench electrode structure (29) has a round shape, shape abnormality is more likely to occur due to process variation. Therefore, dielectric breakdown at the terminal portions can be suppressed by reducing the number of the terminal portions of the second trench electrode structure (29). As a result, ESD (Electro-Static Discharge) resistance of the semiconductor device (1) can be improved.
[Clause 1-2]
The semiconductor device (1) according to Clause 1-1,
wherein the first element region (24) is formed on one side and the other side across the extending electrode (33) in the second direction (Y), and
includes a first trench electrode structure (27) which is formed in the first principal surface (3) of the chip (2), crosses the extending electrode (33), extends across the plurality of first element regions (24) adjacent to each other across the extending electrode (33), and is physically and electrically separated from the second trench electrode structure (29), and
wherein the extending electrode (33) selectively includes a laminated structure of the first electrode layer (34) and the second electrode layer (35) electrically connected to the first trench electrode structure (27) immediately above the first trench electrode structure (27).
[Clause 1-3]
The semiconductor device (1) according to Clause 1-2,
wherein the plurality of first element regions (24) and the plurality of second element regions (25) are alternately arrayed in the first direction (X), and wherein the extending electrode (33) includes the single second electrode layer (35) extending continuously across the plurality of first element regions (24) and the plurality of second element regions (25) and the plurality of first electrode layers (34) selectively disposed in a contact section (37) in which the second electrode layer (35) and the first element region (24) oppose each other by being selectively separated by a non-contact section (36) in which the second electrode layer (35) and the second element region (25) oppose each other.
[Clause 1-4]
The semiconductor device (1) according to Clause 1-3,
wherein the first trench electrode structure (27) includes a first trench (47) and a first embedded electrode (49) embedded in the first trench (47),
wherein the second trench electrode structure (29) includes a second trench (61) and a second embedded electrode (63) embedded in the second trench (61) and covered with the insulating layer (67), and
wherein the first electrode layer (34) includes a first contact layer (38) integrally led out from the first embedded electrode (49) onto the first principal surface (3) and collectively covering the plurality of first trench electrode structures (27).
[Clause 1-5]
The semiconductor device (1) according to Clause 1-4, further including:
a second contact layer (39) which is formed adjacent to the extending electrode (33) in the second direction (Y), is integrally led out from the second embedded electrode (63) onto the first principal surface (3), and collectively covers the plurality of second trench electrode structures (29).
[clause 1-6]
The semiconductor device (1) according to Clause 1-5,
wherein the second contact layer (39) has a shape extending in a band shape in the first direction (X) side by side with the extending electrode (33).
[Clause 1-7]
The semiconductor device (1) according to Clause 1-5, further including:
a third trench electrode structure (28) which extends side by side with the first trench electrode structure (27) in the first element region (24), does not cross the extending electrode (33), and has a terminal portion (31) inside the first element region (24) separated from the extending electrode (33) in the second direction (Y).
[Clause 1-8]
The semiconductor device (1) according to Clause 1-7,
wherein the third trench electrode structure (28) includes a third trench (55) and a third embedded electrode (57) embedded in the third trench (55) and covered with the insulating layer (67), and
further includes a third contact layer (40) which is integrally led out from the third embedded electrode (57) onto the first principal surface (3) at the terminal portion (31) of the third trench electrode structure (28) and
a surface electrode layer (12) which covers the second contact layer (39) and the third contact layer (40) and is connected to the second contact layer (39) and the third contact layer (40).
[Clause 1-9]
The semiconductor device (1) according to Clause 1-8,
wherein the plurality of extending electrodes (33) are formed at intervals in the second direction (Y), and
wherein the surface electrode layer (12) covers at least one each of the first element region (24) and the second element region (25) in a demarcated region (20) sandwiched between the adjacent extending electrodes (33).
[Clause 1-10]
The semiconductor device (1) according to any one of Clauses 1-2 to 1-9, further including:
a drift region (41) of a first conductivity type formed in the chip (2),
wherein the first element region (24) includes an IGBT region (24) having a body region (50) of a second conductivity type formed on the first principal surface (3), an emitter region (51) of the first conductivity type formed in a surface layer portion of the body region (50), a collector region (45) of the second conductivity type formed on the second principal surface (4), and a trench gate structure (27) as the first trench electrode structure (27), and
wherein the second element region (25) includes a diode region (25) having a first impurity region (64) of the second conductivity type formed on the first principal surface (3), a second impurity region (58) of the first conductivity type formed on the second principal surface (4), and a diode-side trench structure (29) as the second trench electrode structure (29) electrically connected to the emitter region (51), and
wherein the extending electrode (33) includes a gate extending electrode (33) electrically connected to the trench gate structure (27).
[Clause 1-11]
The semiconductor device (1) according to Clause 1-10, including:
a well region (87) of the second conductivity type which is formed on the first principal surface (3) immediately below the gate extending electrode (33) and is deeper than the trench gate structure (27) and the diode-side trench structure (29).
[Clause 1-12]
The semiconductor device (1) according to Clause 1-11,
wherein the well region (87) extends across a boundary portion between the IGBT region (24) and the diode region (25) in the first direction (X), crosses the gate extending electrode (33) in the second direction (Y), and is integrally continuous with the body region (50) of the IGBT region (24) and the first impurity region (64) of the diode region (25).
[Clause 1-13]
The semiconductor device (1) according to any one of Clauses 1-10 to 1-12, further including:
a fourth trench electrode structure (29) which is formed in the diode region (25A), does not cross the gate extending electrode (33), and has a terminal portion (32) inside the diode region (25A) separated from the gate extending electrode (33) in the second direction (Y),
wherein the gate extending electrode (33) selectively includes a gate resistor (108) in a portion adjacent to the fourth trench electrode structure (29).
[Clause 1-14]
The semiconductor device (1) according to Clause 1-13, further including:
a gate pad electrode (7) which is electrically connected to the gate extending electrode (33),
wherein the diode region (25A) includes a pad adjacent diode region (25A) which is adjacent to the gate pad electrode (7) in the first direction (X) and in which the fourth trench electrode structure (29) is formed,
wherein the gate extending electrode (33) includes the plurality of second electrode layers (35, 109, 110) separated at a portion crossing the pad adjacent diode region (25A), and
wherein the gate resistor (108) is formed by a portion of the first electrode layer (34) sandwiched by the plurality of second electrode layers (35, 109, 110).
[Clause 1-15]
The semiconductor device (1) according to Clause 1-13, further including:
a gate pad electrode (7) which is electrically connected to the gate extending electrode (33),
wherein the diode region (25) includes a pad adjacent diode region (25) which is adjacent to the gate pad electrode (7) in the second direction (Y) and in which the fourth trench electrode structure (29) is formed,
wherein the gate extending electrode (33) includes the plurality of second electrode layers (35, 109, 110) separated at a portion crossing the pad adjacent diode region (25), and
wherein the gate resistor (108) is formed by a portion of the first electrode layer (34) sandwiched by the plurality of second electrode layers (35, 109, 110).
[Clause 2-1]
A semiconductor device (1) including:
a chip (2) which has a first principal surface (3);
an IGBT region (24) which is formed on the first principal surface (3) of the chip (2);
a diode region (25) which is formed on the first principal surface (3) of the chip (2) and is adjacent to the IGBT region (24) in a first direction (X);
a gate extending electrode (33) which extends continuously across the IGBT region (24) and the diode region (25) in the first direction (X) in a region on the first principal surface (3); and
a trench gate structure (27) which is formed in the first principal surface (3) of the chip (2) and extends across the gate extending electrode (33),
wherein the gate extending electrode (33) selectively includes a gate resistor (108) in a portion crossing the diode region (25) while avoiding a portion immediately above the trench gate structure (27).
According to this configuration, the gate extending electrode (33) includes the gate resistor (108). The gate resistor (108) constitutes a gate resistor for the gate of the IGBT. For example, the gate resistor (108) is effective in suppressing oscillation (noise) caused by parasitic inductance at turn-off. In addition, the gate resistor (108) is selectively disposed in the portion crossing the diode region (25) of the gate extending electrode (33) while avoiding the portion immediately above the trench gate structure (27). Therefore, an increase in an area of the chip (2) can be avoided due to the gate resistor (108). Therefore, it is possible to provide the semiconductor device (1) including the gate resistor (108) without impairing an effective area of the IGBT region (24).
[Clause 2-2]
The semiconductor device (1) according to Clause 2-1, including:
an insulating layer (67) which covers the first principal surface (3),
wherein the plurality of IGBT regions (24) which sandwich the diode region (25) in the first direction (X) are formed,
wherein the gate extending electrode (33) includes a resistance layer (103) formed between the insulating layer (67) and the first principal surface (3) and extending continuously across the IGBT region (24) and the diode region (25) in the first direction (X), and a plurality of wiring layers (104) formed on the insulating layer (67), separated at a portion crossing the diode region (25), and having a lower resistance than the resistance layer (103), and
wherein the gate resistor (108) is formed by a portion of the resistance layer (103) sandwiched by the plurality of wiring layers (104).
[Clause 2-3]
The semiconductor device (1) according to Clause 2-2,
wherein the trench gate structure (27) includes a gate trench (47) and a gate embedded electrode (49) embedded in the gate trench (47), and
wherein the resistance layer (103) is formed in a band shape in plan view with a constant width while being integrally led out from the gate embedded electrode (49) onto the first principal surface (3).
[Clause 2-4]
The semiconductor device (1) according to Clause 2-2,
wherein the gate resistor (108) further includes a resistance trench (113) formed in the first principal surface (3) of the chip (2) and a resistance electrode layer (115) embedded in the resistance trench (113) and integrated with the resistance layer (103).
[Clause 2-5]
The semiconductor device (1) according to Clause 2-4,
wherein the resistance trench (113) is formed in a band shape in plan view that is long in a direction crossing the gate extending electrode (33).
[Clause 2-6]
The semiconductor device (1) according to any one of Clauses 2-1 to 2-5, including:
a gate pad electrode (7) which is electrically connected to the gate extending electrode (33),
wherein the gate extending electrode (33) includes an annular peripheral portion (100) surrounding the gate pad electrode (7) and an extending portion (101) extending in a band shape in the first direction (X) from the peripheral portion (100),
wherein the diode region (25) includes a pad adjacent diode region (25A) adjacent to the gate pad electrode (7) in the first direction (X), and
includes a diode-side trench structure (29) formed in the pad adjacent diode region (25A) and having a terminal portion (32) inside the pad adjacent diode region (25A) separated from the extending portion (101) in a second direction (Y) intersecting the first direction (X), and
wherein the gate resistor (108) is formed adjacent to the terminal portion (32) of the diode-side trench structure (29) in the extending portion (101).
[Clause 2-7]
The semiconductor device (1) according to Clause 2-6,
wherein the plurality of IGBT regions (24) and the plurality of diode regions (25) are alternately arrayed in the first direction (X),
wherein the pad adjacent diode region (25A) is selectively formed in a portion adjacent to the gate pad electrode (7) in the first direction (X), and
wherein in the diode region (25) excluding the pad adjacent diode region (25A), a diode-side second trench structure (29) formed in the first principal surface (3) of the chip (2) and crossing the extending portion (101) is formed.
[Clause 2-8]
The semiconductor device (1) according to Clause 2-6 or 2-7,
wherein the gate pad electrode (7) is disposed at a peripheral edge portion of the chip (2),
wherein the gate extending electrode (33) includes an outer extending electrode (16) formed along the peripheral edge portion of the chip (2) from the gate pad electrode (7) and surrounding an active region (18), and an inner extending electrode (17, 33) crossing the active region (18) and having one end portion and the other end portion connected to different positions in the outer extending electrode (16), and
wherein the gate resistor (108) is formed in the inner extending electrode (17, 33).
[Clause 2-9]
The semiconductor device (1) according to any one of Clauses 2-1 to 2-5, including:
a gate pad electrode (7) which is electrically connected to the gate extending electrode (33),
wherein the gate extending electrode (33) includes an annular peripheral portion (100) surrounding the gate pad electrode (7) and an extending portion (101) extending in a band shape in the first direction (X) from the peripheral portion (100),
wherein the diode region (25) includes a pad adjacent diode region (25A) adjacent to the gate pad electrode (7) in a second direction (Y) intersecting the first direction (X), and
includes a diode-side trench structure (29) formed in the pad adjacent diode region (25A) and having a terminal portion (32) inside the pad adjacent diode region (25A) separated from the peripheral portion (100) in the second direction (Y), and
wherein the gate resistor (108) is formed adjacent to the terminal portion (32) of the diode-side trench structure (29) in the peripheral portion (100) of the gate extending electrode (33).
[Clause 2-10]
The semiconductor device (1) according to Clause 2-9,
wherein the plurality of IGBT regions (24) and the plurality of diode regions (25) are alternately arrayed in the first direction (X),
wherein the pad adjacent diode region (25A) is selectively formed in a portion adjacent to the gate pad electrode (7) in the second direction (Y), and
wherein in the diode region (25) excluding the pad adjacent diode region (25A), a diode-side second trench structure (29) formed in the first principal surface (3) of the chip (2) and crossing the extending portion (101) is formed.
[Clause 2-11]
The semiconductor device (1) according to any one of Clauses 2-1 to 2-10,
wherein the gate resistor (108) is formed of polysilicon.
[Clause 3-1]
A semiconductor device (1) including:
a chip (2) which has a first principal surface (3) and a second principal surface (4);
a first element region (24) which is formed on the first principal surface (3) of the chip (2);
a second element region (25) which is formed on the first principal surface (3) of the chip (2) and is adjacent to the first element region (24) in a first direction (X);
a gate extending electrode (33) which extends continuously across the first element region (24) and the second element region (25) in the first direction (X) in a region on the first principal surface (3);
a trench gate structure (27) which is formed in the first principal surface (3) of the first element region (24) and extends across the gate extending electrode (33);
a second trench electrode structure (29) which is formed in the first principal surface (3) of the second element region (25), does not cross the gate extending electrode (33), and has a terminal portion (32) inside the second element region (25) separated from the gate extending electrode (33) in a second direction (Y) intersecting the first direction (X);
a gate auxiliary trench (95) which is formed immediately below the gate extending electrode (33) in a portion adjacent to the second element region (25) in the second direction (Y); and
a gate auxiliary embedded electrode (97) which is embedded in the gate auxiliary trench (95) through a gate insulating film (96) and is electrically connected to the gate extending electrode (33).
According to this configuration, the gate auxiliary embedded electrode (97) electrically connected to the gate extending electrode (33) is formed. As a result, since the gate capacitance can be increased, the ESD resistance of the gate can be improved. In addition, the gate auxiliary embedded electrode (97) is disposed in an empty space immediately below the gate extending electrode (33). Therefore, an increase in an area of the chip (2) and an increase in a density of a gate trench (47) can be avoided due to the gate auxiliary embedded electrode (97). As a result, it is possible to suppress an increase in chip cost and an increase in process difficulty.
[Clause 3-2]
The semiconductor device (1) according to Clause 3-1,
wherein the gate auxiliary trench (95) is a trench that is long along the second direction (Y).
[Clause 3-3]
The semiconductor device (1) according to Clause 3-2.
wherein the gate auxiliary trench (95) includes a plurality of elliptical trenches whose major axis direction coincides with the second direction (Y).
[Clause 3-4]
The semiconductor device (1) according to Clause 3-2,
wherein the gate auxiliary trench (95) includes a plurality of band-shaped trenches whose length direction coincides with the second direction (Y).
[Clause 3-5]
The semiconductor device (1) according to any one of Clauses 3-2 to 3-4,
wherein the gate auxiliary trench (95) has an end portion (98) protruding further outward than the gate extending electrode (33) in the second direction (Y).
[Clause 3-6]
The semiconductor device (1) according to any one of Clauses 3-1 to 3-5,
wherein the trench gate structure (27) includes a gate trench (47) and a gate embedded electrode (49) embedded in the gate trench (47), and
wherein the gate extending electrode (33) includes a first electrode layer (34) integrally led out from the gate embedded electrode (49) and the gate auxiliary embedded electrode (97) onto the first principal surface (3) and collectively covering the gate trench (47) and the gate auxiliary trench (95) and a second electrode layer (35) formed on the first electrode layer (34) through an insulating layer (67) and extending in the first direction (X) across the gate trench (47) and the gate auxiliary trench (95).
[Clause 3-7]
The semiconductor device (1) according to Clause 3-6,
wherein the first electrode layer (34) has a band shape extending with a constant width in the first direction (X), and
wherein the second electrode layer (35) has a band shape extending with a constant width in the first direction (X).
[Clause 3-8]
The semiconductor device (1) according to any one of Clauses 3-1 to 3-7, including:
a drift region (41) of a first conductivity type formed in the chip (2),
wherein the first element region (24) includes an IGBT region (24) having a body region (50) of a second conductivity type formed on the first principal surface (3), an emitter region (51) of the first conductivity type formed in a surface layer portion of the body region (50), a collector region (45) of the second conductivity type formed on the second principal surface (4), and the trench gate structure (27), and
wherein the second element region (25) includes a diode region (25) having a first impurity region (64) of the second conductivity type formed on the first principal surface (3), a second impurity region (58) of the first conductivity type formed on the second principal surface (4), and a diode-side trench structure (29) as the second trench electrode structure (29) electrically connected to the emitter region (51).
[Clause 3-9]
The semiconductor device (1) according to Clause 3-8,
wherein the diode-side trench structure (29) and the gate auxiliary trench (95) are formed on the same virtual straight line (99) extending along the second direction (Y).
[Clause 3-10]
The semiconductor device (1) according to Clause 3-8 or 3-9,
wherein the gate extending electrode (33) further selectively includes a gate resistor (108) in a portion crossing the diode region (25) while avoiding a portion immediately above the trench gate structure (27).
[Clause 3-11]
The semiconductor device (1) according to Clause 3-10, including:
an insulating layer (67) which covers the first principal surface (3),
wherein the plurality of IGBT regions (24) which sandwich the diode region (25) in the first direction (X) are formed,
wherein the gate extending electrode (33) includes a resistance layer (103) formed between the insulating layer (67) and the first principal surface (3) and extending continuously across the IGBT region (24) and the diode region (25) in the first direction (X), and a plurality of wiring layers (104) formed on the insulating layer (67), separated at a portion crossing the diode region (25), and having a lower resistance than the resistance layer (103), and
wherein the gate resistor (108) is formed by a portion of the resistance layer (103) sandwiched by the plurality of wiring layers (104).
[Clause 3-12]
The semiconductor device (1) according to Clause 3-11,
wherein the gate resistor (108) further includes a resistance trench (113) formed in the first principal surface (3) of the chip (2) and a resistance embedded electrode (115) embedded in the resistance trench (113) and integrated with the resistance layer (103).
[Clause 3-13]
The semiconductor device (1) according to Clause 3-12,
wherein the resistance trench (113) is formed in a band shape in plan view that is long in a direction crossing the gate extending electrode (33).
[Clause 3-14]
The semiconductor device (1) according to any one of Clauses 3-10 to 3-13, further including:
a gate pad electrode (7) which is electrically connected to the gate extending electrode (33),
wherein the diode region (25) includes a pad adjacent diode region (25A) adjacent to the gate pad electrode (7) in the first direction (X), and
wherein the gate resistor (108) is formed at a position near the pad adjacent diode region (25A) in the gate extending electrode (33).
[Clause 3-15]
The semiconductor device (1) according to any one of Clauses 3-10 to 3-13, further including:
a gate pad electrode (7) which is electrically connected to the gate extending electrode (33),
wherein the diode region (25) includes a pad adjacent diode region (25A) adjacent to the gate pad electrode (7) in the second direction (Y), and
wherein the gate resistor (108) is formed at a position near the pad adjacent diode region (25A) in the gate extending electrode (33).

1. A semiconductor device comprising:
a chip which has a first principal surface and a second principal surface;
an insulating layer which covers the first principal surface;
an extending electrode which extends in a region on the first principal surface in a first direction, the extending electrode which includes a first electrode layer formed between the insulating layer and the first principal surface and a second electrode layer formed on the insulating layer and electrically connected to the first electrode layer;
a first element region which includes an element electrically connected to the extending electrode;
a second element region which is adjacent to the first element region in the first direction and is formed on one side and the other side across the extending electrode in a second direction intersecting the first direction; and
a second trench electrode structure which is formed in the first principal surface of the chip, crosses the extending electrode, and extends across the plurality of second element regions adjacent to each other across the extending electrode,
wherein the extending electrode does not include the first electrode layer and selectively includes the second electrode layer immediately above the second trench electrode structure.

2. The semiconductor device according to claim 1,
wherein the first element region is formed on one side and the other side across the extending electrode in the second direction, and
includes a first trench electrode structure which is formed in the first principal surface of the chip, crosses the extending electrode, extends across the plurality of first element regions adjacent to each other across the extending electrode, and is physically and electrically separated from the second trench electrode structure, and
wherein the extending electrode selectively includes a laminated structure of the first electrode layer and the second electrode layer electrically connected to the first trench electrode structure immediately above the first trench electrode structure.

3. The semiconductor device according to claim 2,
wherein the plurality of first element regions and the plurality of second element regions are alternately arrayed in the first direction, and
wherein the extending electrode includes the single second electrode layer extending continuously across the plurality of first element regions and the plurality of second element regions and the plurality of first electrode layers selectively disposed in a contact section in which the second electrode layer and the first element region oppose each other by being selectively separated by a non-contact section in which the second electrode layer and the second element region oppose each other.

4. The semiconductor device according to claim 3,
wherein the first trench electrode structure includes a first trench and a first embedded electrode embedded in the first trench,
wherein the second trench electrode structure includes a second trench and a second embedded electrode embedded in the second trench and covered with the insulating layer, and
wherein the first electrode layer includes a first contact layer integrally led out from the first embedded electrode onto the first principal surface and collectively covering the plurality of first trench electrode structures.

5. The semiconductor device according to claim 4, further comprising:
a second contact layer which is formed adjacent to the extending electrode in the second direction, is integrally led out from the second embedded electrode onto the first principal surface, and collectively covers the plurality of second trench electrode structures.

6. The semiconductor device according to claim 5,
wherein the second contact layer has a shape extending in a band shape in the first direction side by side with the extending electrode.

7. The semiconductor device according to claim 5, further comprising:
a third trench electrode structure which extends side by side with the first trench electrode structure in the first element region, does not cross the extending electrode, and has a terminal portion inside the first element region separated from the extending electrode in the second direction.

8. The semiconductor device according to claim 7,
wherein the third trench electrode structure includes a third trench and a third embedded electrode embedded in the third trench and covered with the insulating layer, and
further includes a third contact layer which is integrally led out from the third embedded electrode onto the first principal surface at the terminal portion of the third trench electrode structure and
a surface electrode layer which covers the second contact layer and the third contact layer and is connected to the second contact layer and the third contact layer.

9. The semiconductor device according to claim 8,
wherein the plurality of extending electrodes are formed at intervals in the second direction, and
wherein the surface electrode layer covers at least one each of the first element region and the second element region in a demarcated region sandwiched between the adjacent extending electrodes.

10. The semiconductor device according to claim 2, further comprising:
a drift region of a first conductivity type formed in the chip,
wherein the first element region includes an IGBT region having a body region of a second conductivity type formed on the first principal surface, an emitter region of the first conductivity type formed in a surface layer portion of the body region, a collector region of the second conductivity type formed on the second principal surface, and a trench gate structure as the first trench electrode structure, and
wherein the second element region includes a diode region having a first impurity region of the second conductivity type formed on the first principal surface, a second impurity region of the first conductivity type formed on the second principal surface, and a diode-side trench structure as the second trench electrode structure electrically connected to the emitter region, and
wherein the extending electrode includes a gate extending electrode electrically connected to the trench gate structure.

11. The semiconductor device according to claim 10, comprising:
a well region of the second conductivity type which is formed on the first principal surface immediately below the gate extending electrode and is deeper than the trench gate structure and the diode-side trench structure.

12. The semiconductor device according to claim 11,
wherein the well region extends across a boundary portion between the IGBT region and the diode region in the first direction, crosses the gate extending electrode in the second direction, and is integrally continuous with the body region of the IGBT region and the first impurity region of the diode region.

13. The semiconductor device according to claim 10, further comprising:
a fourth trench electrode structure which is formed in the diode region, does not cross the gate extending electrode, and has a terminal portion inside the diode region separated from the gate extending electrode in the second direction,
wherein the gate extending electrode selectively includes a gate resistor in a portion adjacent to the fourth trench electrode structure.

14. The semiconductor device according to claim 13, further comprising:
a gate pad electrode which is electrically connected to the gate extending electrode,
wherein the diode region includes a pad adjacent diode region which is adjacent to the gate pad electrode in the first direction and in which the fourth trench electrode structure is formed,
wherein the gate extending electrode includes the plurality of second electrode layers separated at a portion crossing the pad adjacent diode region, and
wherein the gate resistor is formed by a portion of the first electrode layer sandwiched by the plurality of second electrode layers.

15. The semiconductor device according to claim 13, further comprising:
a gate pad electrode which is electrically connected to the gate extending electrode,
wherein the diode region includes a pad adjacent diode region which is adjacent to the gate pad electrode in the second direction and in which the fourth trench electrode structure is formed,
wherein the gate extending electrode includes the plurality of second electrode layers separated at a portion crossing the pad adjacent diode region, and
wherein the gate resistor is formed by a portion of the first electrode layer sandwiched by the plurality of second electrode layers.
